(19) United States
(12) Patent Application Publication
(10) Pub. No.: US 2023/0221644 A1
(43) Pub. Date: Jul. 13, 2023

(54) METHOD FOR PRODUCING COMPOSITION FOR FORMING NON-PHOTOSENSITIVE UPPER LAYER FILM, PATTERN FORMING METHOD, AND METHOD FOR MANUFACTURING ELECTRONIC DEVICE

(71) Applicant: FUJIFILM Corporation, Tokyo (JP)

(72) Inventors: Naohiro TANGO, Haibara-gun (JP); Kei YAMAMOTO, Haibara-gun (JP)

(73) Assignee: FUJIFILM Corporation, Tokyo (JP)

(21) Appl. No.: 18/176,150

(22) Filed: Feb. 28, 2023

Related U.S. Application Data
(63) Continuation of application No. PCT/JP2021/031244, filed on Aug. 25, 2021.

(30) Foreign Application Priority Data
Aug. 31, 2020 (JP) 2020-145924

(51) Int. Cl. G03F 7/11; C08F 220/28; C08F 220/38; C08F 220/24

(52) U.S. Cl. CPC G03F 7/11; C08F 220/24; C08F 220/281; C08F 220/282; C08F 220/387

(57) ABSTRACT

A method for producing a composition for forming a non-photosensitive upper layer film that is disposed on a workpiece and a photosensitive resist film, the production method includes cleaning a production device for a composition X_{A} for forming a non-photosensitive upper layer film with a cleaning liquid to clean the production device until a concentration of a resin included in the cleaning liquid reaches 10 ppm by mass or less, discharging the cleaning liquid from the production device, and producing the composition X_{A} for forming a non-photosensitive upper layer film using the production device. The cleaning, the discharging, and the producing are performed in this order.

### CROSS REFERENCE TO RELATED APPLICATION

This is a continuation of International Application No. PCT/JP2021/031244 filed on Aug. 25, 2021, and claims priority from Japanese Patent Application No. 2020-145924 filed on Aug. 31, 2020, the entire disclosures of which are incorporated herein by reference.

### BACKGROUND OF THE INVENTION

### 1. Field of the Invention

The present invention relates to a method for producing a composition for forming a non-photosensitive upper layer film, a pattern forming method, and a method for manufacturing an electronic device.

### 2. Description of the Related Art

In processes for manufacturing semiconductor devices such as an integrated circuit (IC) and a large scale integrated circuit (LSI), microfabrication by lithography using a photosensitive resist film has been performed.

Examples of the lithography method include a method in which a photosensitive resist film is formed on a workpiece (typically a silicon wafer) with a photosensitive resist composition, and the photosensitive resist film is exposed and developed to form a resist pattern, and the resist pattern is used as a mask to transfer the pattern to the workpiece.

In recent years, as a method for forming a resist pattern, a liquid immersion exposure method has been widely used. This method has an advantage that even in a case where the number of apertures (NA) of a lens is increased, a focal depth is less likely to decrease, and further, a high resolution can be obtained.

On the other hand, in the liquid immersion exposure method, it is known that since a photosensitive resist film comes into contact with an immersion liquid during exposure, there is a concern that the photosensitive resist film may be deteriorated, and there is also a concern that components adversely affecting the immersion liquid the photosensitive resist film may exude.

As a solution for avoiding such problems, a method in which an upper layer film is provided on a photosensitive resist film (that is, between the photosensitive resist film and the exposure light source) so that the photosensitive resist film and the immersion liquid do not come into direct contact with each other (for example, JP2010-266886A).

In addition, JP2019-40201A and JP2015-197646A disclose a method for producing a resist composition by cleaning a production device which is used for producing a resist composition to be used in a step in the manufacture of a semiconductor device, with a cleaning liquid, and circulating the cleaning liquid until a concentration of metal components included in the cleaning liquid reaches 5 parts per billion (ppb) or less.

### SUMMARY OF THE INVENTION

It is desirable that a pattern formed on a workpiece has fewer defects. Here, the defects mean unintended recesses, chips, or disconnections in the patterns, or patterns having an undesired size.

An object of the present invention is to provide a method for producing a composition for forming a non-photosensitive upper layer film, which is capable of forming a pattern having suppressed generation of defects, a pattern forming method, and a method for manufacturing an electronic device.

The present inventors have found that the objects can be accomplished by the following configurations.

<1> A method for producing a composition for forming a non-photosensitive upper layer film that is disposed on a workpiece and a photosensitive resist film, the production method comprising:

cleaning a production device for a composition X_{A} for forming a non-photosensitive upper layer film with a cleaning liquid to clean the production device until a concentration of a resin included in the cleaning liquid reaches 10 ppm by mass or less, discharging the cleaning liquid from the production device, and producing the composition X_{A} for forming a non-photosensitive upper layer film using the production device, the cleaning, the discharging, and the producing being performed in this order.

<2> The method for producing a composition for forming a non-photosensitive upper layer film as described in <1>,

in which the concentration of the resin is calculated using a gel permeation chromatography analysis method.

<3> The method for producing a composition for forming a non-photosensitive upper layer film as described in <1> or <2>,
in which the production device includes a preparation tank, a pipe, a pump, a filtration machine, and a valve, and
in which the inside of each of the preparation tank, the pipe, the pump, the filtration machine, and the valve is cleaned by circulating the cleaning liquid.

<4> The method for producing a composition for forming a non-photosensitive upper layer film as described in any one of <1> to <3>,
in which the production device is a production device that is used for producing a composition X_{B} for forming a non-photosensitive upper layer film containing a solvent S_{B} before producing the composition X_{A} for forming a non-photosensitive upper layer film, and
   |SP_{w} - SP_{B}|, which is an absolute value of a difference between a solubility parameter SP_{w} of the cleaning liquid and a solubility parameter SP_{B} of the solvent S_{B}, is less than 1.0 MPa^{½}.

<5> The method for producing a composition for forming a non-photosensitive upper layer film as described in <4>,
in which the cleaning of the production device is performed using at least two kinds of cleaning liquids, a first cleaning liquid and a second cleaning liquid,
the composition X_{A} for forming a non-photosensitive upper layer film contains a solvent S_{A},
   |SP_{W1} - SP_{B}|, which is an absolute value of an absolute value of a difference between a solubility parameter SP_{W1} of the first cleaning liquid and the solubility parameter SP_{B} of the solvent S_{B}, is less than 1.0 MPa^{½}, and
   |SP_{w2} - SP_{A}|, which is an absolute value of a difference between a solubility parameter SPw₂ of the second cleaning liquid and the solubility parameter SP_{A} of the solvent S_{A}, is less than 1.0 MPa^{½}.

<6> The method for producing a composition for forming a non-photosensitive upper layer film as described in any one of <1> to <5>,

in which the cleaning liquid includes at least 4-methyl-2-pentanol.

<7> The method for producing a composition for forming a non-photosensitive upper layer film as described in any one of <1> to <6>,

in which a transmittance of an ArF excimer laser light of a non-photosensitive upper layer film, which has a film thickness of 30 nm and is formed using the composition X_{A} for forming a non-photosensitive upper layer film, is 80% or more.

<8> The method for producing a composition for forming a non-photosensitive upper layer film as described in any one of <1> to <7>,

in which the composition X_{A} for forming a non-photosensitive upper layer film contains at least one of an alcohol-based solvent or an ether-based solvent.

<9> The method for producing a composition for forming a non-photosensitive upper layer film as described in any one of <1> to <8>,

in which the composition X_{A} for forming a non-photosensitive upper layer film contains a resin having a repeating unit represented by General Formula (I).

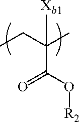

In General Formula (I), X_{b1} represents a hydrogen atom, an alkyl group, a cyano group, or a halogen atom, and R₂ represents an organic group.

<10> The method for producing a composition for forming a non-photosensitive upper layer film as described in <9>,

in which the resin has an acid group.

<11> The method for producing a composition for forming a non-photosensitive upper layer film as described in <9> or <10>,

in which the resin has a fluorine-containing group.

<12> The method for producing a composition for forming a non-photosensitive upper layer film according to any one of <9> to <11>,

in which the resin has no acid-decomposable group.

<13> The method for producing a composition for forming a non-photosensitive upper layer film as described in any one of <1> to <12>,

in which the composition X_{A} for forming a non-photosensitive upper layer film contains two or more kinds of resins.

<14> A pattern forming method comprising disposing a photosensitive resist film on a workpiece, forming a non-photosensitive upper layer film using a composition for forming a non-photosensitive upper layer film produced by the method for producing a composition for forming a non-photosensitive upper layer film as described in any one of <1> to <13>, on the photosensitive resist film, and exposing and developing the photosensitive resist film to form a pattern.

<15> A method for manufacturing an electronic device, comprising the pattern forming method as described in <14>.

According to the present invention, it is possible to provide a method for producing a composition for forming a non-photosensitive upper layer film, which is capable of forming a pattern having suppressed generation of defects, a pattern forming method, and a method for manufacturing an electronic device.

### BRIEF DESCRIPTION OF THE DRAWINGS

FIG. 1 is a flow chart for explaining an example of a method for producing a composition for forming a non-photosensitive upper layer film.

FIG. 2 is a schematic view of an embodiment of a production device for a composition for forming a non-photosensitive upper layer film.

FIG. 3 is a schematic view showing an example of a defect in a pattern.

FIG. 4 is a schematic view showing an example of a defect in a pattern.

### DESCRIPTION OF THE PREFERRED EMBODIMENTS

Hereinafter, an example of a form for carrying out the present invention will be described.

In the present specification, a numerical value range expressed using “to” means a range that includes the preceding and succeeding numerical values of “to” as a lower limit value and an upper limit value, respectively.

In notations for a group (atomic group) in the present specification, in a case where the group is noted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

In addition, an “organic group” in the present specification refers to a group including at least one carbon atom.

Furthermore, in the present specification, the types of substituents, the positions of substituents, and the number of substituents in a case where it is described that “a substituent may be contained” are not particularly limited. The number of the substituents may be, for example, one, two, three, or more. Examples of the substituent include a monovalent non-metal atomic group excluding a hydrogen atom, and the substituent can be selected from, for example, the following substituent T.

### Substituent T

Examples of the substituent T include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butylsulfanyl group; arylsulfanyl groups such as a phenylsulfanyl group and a p-tolylsulfanyl group; alkyl groups; cycloalkyl groups; aryl groups; heteroaryl groups; a hydroxyl group; a carboxy group; a formyl group; a sulfo group; a cyano group; an alkylaminocarbonyl group; an arylaminocarbonyl group; a sulfonamide group; a silyl group; an amino group; a monoalkylamino group; a dialkylamino group; an arylamino group, a nitro group; a formyl group; and a combination thereof.

The bonding direction of divalent groups noted in the present specification is not limited unless otherwise specified. For example, in a compound represented by General Formula “L-M-N”, M may be either *1—OCO—C(CN)═CH—*2 or *1—CH═C(CN)—COO—*2 assuming that in a case where M is —OCO—C(CN)═CH—, a position bonded to the L side is defined as *1 and a position bonded to the N side is defined as *2.

“(Meth)acryl” in the present specification is a generic term encompassing acryl and methacryl, and means “at least one of acryl or methacryl”. Similarly, “(meth)acrylic acid” is a generic term encompassing acrylic acid and methacrylic acid, and means “at least one of acrylic acid or methacrylic acid”.

In the present specification, a weight-average molecular weight (Mw), a number-average molecular weight (Mn), and a dispersity (also described as a molecular weight distribution) (Mw/Mn) of a resin are defined as values expressed in terms of polystyrene by means of gel permeation chromatography (GPC) measurement (solvent: tetrahydrofuran, flow amount (amount of a sample injected): 10 µL, columns: TSK gel Multipore HXL-M manufactured by Tosoh Corporation, column temperature: 40° C., flow rate: 1.0 mL/min, and detector: differential refractive index detector) using a GPC apparatus (HLC-8120GPC manufactured by Tosoh Corporation).

“Light” in the present specification means actinic rays or radiation. The actinic rays or the radiation means, for example, a bright line spectrum of a mercury lamp, far ultraviolet rays typified by an excimer laser, extreme ultraviolet rays (EUV), X-rays, electron beams (EB), or the like.

Unless otherwise specified, “exposure” in the present specification encompasses not only exposure by a bright line spectrum of a mercury lamp, far ultraviolet rays typified by an excimer laser, extreme ultraviolet rays, X-rays, EUV, or the like, but also lithography by particle beams such as electron beams and ion beams.

The method for producing a composition for forming a non-photosensitive upper layer film according to an embodiment of the present invention is a method for producing a composition for forming a non-photosensitive upper layer film that is disposed on a workpiece and a photosensitive resist film, the method including cleaning a production device for a composition X_{A} for forming a non-photosensitive upper layer film with a cleaning liquid to clean the production device until a concentration of a resin included in the cleaning liquid reaches 10 parts per million (ppm) by mass or less, subsequently discharging the cleaning liquid from the production device, and then producing the composition X_{A} for forming a non-photosensitive upper layer film using the production device.

The composition for forming a non-photosensitive upper layer film produced by the method for producing a composition for forming a non-photosensitive upper layer film of the embodiment of the present invention is also referred to as a “composition X_{A} for forming a non-photosensitive upper layer film”. Details of the composition X_{A} for forming a non-photosensitive upper layer film will be described later.

In the present invention, before producing the composition X_{A} for forming a non-photosensitive upper layer film, first, the production device for the composition X_{A} for forming a non-photosensitive upper layer film is cleaned with a cleaning liquid. The cleaning of the production device with the cleaning liquid is intended to remove the resin present in the production device.

In a case of producing a composition for forming a non-photosensitive upper layer film, a predetermined production device is often used repeatedly. Therefore, in a production device used for producing the composition X_{A} for forming a non-photosensitive upper layer film, a resin included in the previously produced composition for forming a non-photosensitive upper layer film (also referred to as a “composition X_{B} for forming a non-photosensitive upper layer film”) may remain in the production device. In addition, it is also considered that a resin derived from the material of the component constituting the production device remains in the production device. It is considered that the composition for forming a non-photosensitive upper layer film produced using the production device in which the resin remains may include a resin that is not originally intended to be contained, which is thus considered to cause defects generated in a pattern. In particular, in the formation of an ultrafine pattern (for example, a pattern having a line width of 50 nm or less), it is considered that the influence of the residual resin is significant.

Therefore, in the present invention, the production device is cleaned before producing the composition X_{A} for forming a non-photosensitive upper layer film to remove the resin remaining in the production device to a certain range. As a result of this, it is considered that a pattern having no or fewer defects can be obtained.

Furthermore, the composition X_{A} for forming a non-photosensitive upper layer film and the composition X_{B} for forming a non-photosensitive upper layer film may be the same compositions or different compositions.

In the present invention, the cleaning of the production device is performed until the concentration of the resin included in the cleaning liquid reaches 10 ppm by mass or less. At least a part of the cleaning liquid may be taken out from the production device and analyzed during the cleaning to confirm that the concentration of the resin is 10 ppm by mass or less, or the cleaning liquid (finally discharged substance) after the cleaning may be analyzed to confirm that the concentration of the resin is 10 ppm by mass or less.

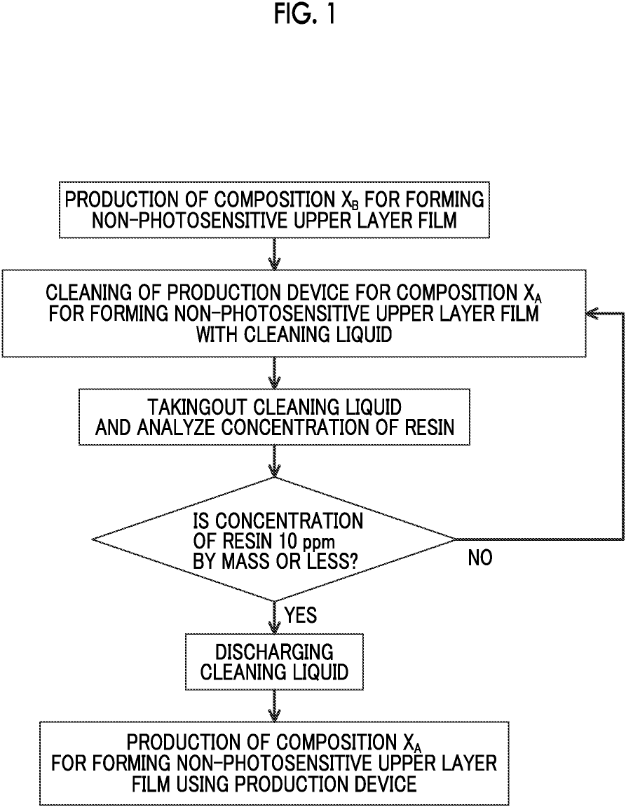

FIG. 1 is a flow chart for explaining an example of a method for producing a composition X_{A} for forming a non-photosensitive upper layer film.

The flow chart of FIG. 1 is regarding a case where the composition X_{A} for forming a non-photosensitive upper layer film is produced using the production device used in the production of the composition X_{B} for forming a non-photosensitive upper layer film.

As shown in FIG. 1, as an example of a preferred aspect of the present invention, mention may be made an aspect in which the cleaning of the production device is performed, at least a part of the cleaning liquid is once taken out from the production device for analysis, and thus, in a case where concentration of the resin in the cleaning liquid taken out is not 10 ppm by mass or less, the cleaning of the production device with the cleaning liquid is performed again, and the operation in which the cleaning liquid is taken out to analyze the concentration of the resin is repeated until the concentration of the resin in the cleaning liquid taken out reaches 10 ppm by mass or less. By passing the cleaning liquid that has cleaned the inside of the production device through a filtration machine as will be described later, the resin removed from the inside of the production device can be separated from the cleaning liquid, and thus, the concentration of the resin in the cleaning liquid can be reduced.

From the viewpoint of reducing the defects of the pattern, a smaller concentration of the resin in the cleaning liquid for cleaning the production device is more preferable. The concentration of the resin in the cleaning liquid with which the production device has been cleaned is preferably 8 ppm by mass or less, more preferably 6 ppm by mass or less, still more preferably 4 ppm by mass or less, particularly preferably 2 ppm by mass or less, and most preferably 1 ppm by mass or less.

The method for analyzing the concentration of the resin included in the cleaning liquid obtained by cleaning the production device is not particularly limited, and examples thereof include a gel permeation chromatography (GPC) analysis method, a high-performance liquid chromatography (HPLC) analysis method, and a method using nuclear magnetic resonance (NMR) spectrometer. In the present invention, it is particularly preferable to calculate the concentration of the resin included in the cleaning liquid by using the gel permeation chromatography analysis method. Furthermore, in the present invention, the “concentration of the resin included in the cleaning liquid” is preferably a concentration of the resin included in the cleaning liquid having a weight-average molecular weight (Mw) of 3,000 or more.

In the gel permeation chromatography analysis method, the measurement is performed under the conditions of a solvent: tetrahydrofuran, a flow rate (sample injection amount): 10 µL, columns: TSK gel Multipore HXL-M manufactured by Tosoh Corporation, a column temperature: 40° C., a flow rate: 1.0 mL/min, and a detector: differential refractive index detector, using HLC-8120GPC manufactured by Tosoh Corporation as a GPC device. In order to calculate the concentration of the resin, it is preferable to examine a relationship between the peak area and the concentration in the chromatogram in advance to prepare a calibration line.

### Production Device for Composition X_{A} for Forming Non-Photosensitive Upper Layer Film

The production device for the composition X_{A} for forming a non-photosensitive upper layer film is not particularly limited, and a known one as a production device for the composition for forming a non-photosensitive upper layer film can be used.

The production device for the composition X_{A} for forming a non-photosensitive upper layer film preferably includes at least a preparation tank, and more preferably includes a preparation tank, a pipe, a pump, a filtration machine, and a valve.

It is preferable that the production device for the composition X_{A} for forming a non-photosensitive upper layer film includes a preparation tank, a pipe, a pump, a filtration machine, and a valve, and the inside of each of the preparation tank, the pipe, the pump, the filtration machine, and the valve (in particular, a portion of the preparation tank, the pipe, the pump, the filtration machine, and the valve, which can come into contact with the composition X_{A} for forming a non-photosensitive upper layer film during the production of the composition X_{A} for forming a non-photosensitive upper layer film), is cleaned by circulating the cleaning liquid.

It is preferable that the production device for the composition X_{A} for forming a non-photosensitive upper layer film further has a stirrer in the preparation tank.

The filtration machine is preferably equipped with a filter.

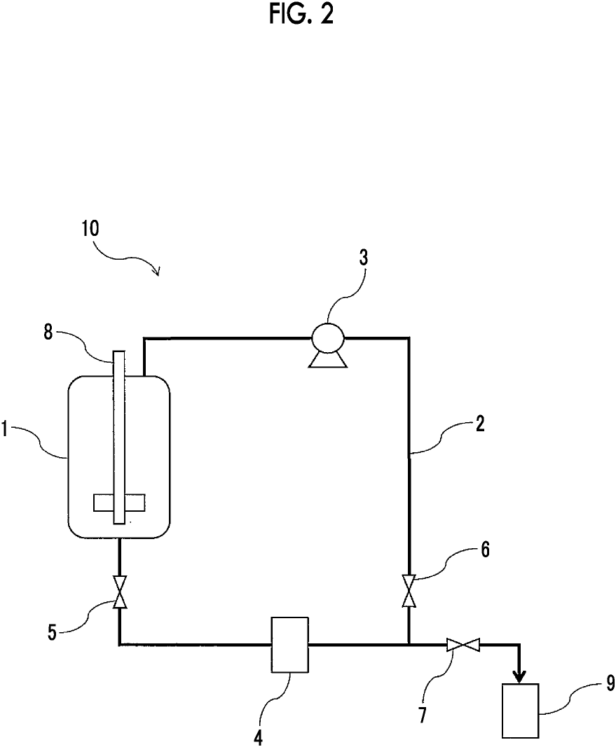

FIG. 2 is a schematic view of an embodiment of a production device for a composition for forming a non-photosensitive upper layer film.

The production device 10 for a composition for forming a non-photosensitive upper layer film shown in FIG. 2 includes a preparation tank 1, a pipe 2, a pump 3, a filtration machine 4, and valves 5 to 7. The preparation tank 1, the pump 3, the filtration machine 4, and the valves 5 to 7 are connected by the pipe 2. In addition, the production device 10 has a stirrer 8 in the preparation tank 1.

The cleaning liquid can be circulated by filling a cleaning liquid in the preparation tank 1, opening the valve 5 (preparation tank valve) and the valve 6 (circulation valve), and closing the valve 7 (extraction valve) to start the pump 3. The pump is not particularly limited and examples thereof include a rotary pump, a diaphragm pump, a metering pump, a chemical pump, a plunger pump, a bellows pump, a gear pump, a vacuum pump, an air pump, and a liquid pump, as well as commercially available pumps as appropriate. A position where the pump is disposed is not particularly limited.

By passing the cleaning liquid through the filtration machine 4, the concentration of the resin included in the cleaning liquid can be reduced. The filtration machine 4 is preferably equipped with a filter.

The type of the filter is not particularly limited, and a known filter can be used.

The pore diameter of the filter is preferably 200 nm or less, more preferably 100 nm or less, still more preferably 50 nm or less, particularly preferably 30 nm or less, and most preferably 20 nm or less.

As a material of the filter, for example, fluororesins such as polytetrafluoroethylene, perfluoroalkoxyalkane, a perfluoroethylenepropene copolymer, polyvinylidenefluoride, and an ethylenetetrafluoroethylene copolymer, polyolefin resins such as polypropylene and polyethylene, polyamide resins such as nylon 6 and nylon 66, and polyimide resins (examples of the polyimide filter include the polyimide filters described in JP2017-064711A and JP2017-064712A) are preferable.

As the filter, a filter which has been cleaned with an organic solvent in advance may be used.

In the filtration using a filter, a plurality of filters connected in series or in parallel may be used. In a case where the plurality of filters are used, a combination of filters having different pore diameters and/or materials may be used. In addition, in the filtration with a filter, circulation-filtration may be carried out. As a method of circulation-filtration, for example, the method disclosed in JP2002-062667A is preferable.

As the filter, a filter having a reduced amount of elutes as disclosed in JP2016-201426A is preferable.

After the filter filtration, impurities may be further removed by an adsorbing material.

A liquid contact part (a part in contact with the liquid) in the production device may be lined or coated with a fluororesin and the like.

The preparation tank 1 is not particularly limited as long as it can accommodate the components included in the composition for forming a non-photosensitive upper layer film.

A shape of the bottom part of the preparation tank 1 is not particularly limited, and examples thereof include a dish-shaped end plate shape, a semi-elliptical end plate shape, a plan end plate shape, and a conical end plate shape.

Baffle plates may be installed in the preparation tank 1 in order to improve the stirring efficiency.

The number of the baffle plates is not particularly limited, and is preferably 2 to 8.

A width of the baffle plate in the horizontal direction of the preparation tank 1 is not particularly limited, and is preferably ⅛ to ½ of the diameter of the preparation tank 1.

A length of the baffle plate in the height direction of the preparation tank 1 is not particularly limited, but is preferably ½ or more, more preferably ⅔ or more, and still more preferably ¾ or more of the height from the bottom part of the preparation tank 1 to the liquid level of the component to be charged.

The stirrer 8 is preferably driven by a drive source (for example, a motor). In a case where the stirring shaft is rotated by the drive source, the stirring blade is rotated and the respective components put into the preparation tank 1 are stirred.

The shape of the stirring blade is not particularly limited, and examples thereof include a paddle blade, a propeller blade, and a turbine blade.

The preparation tank 1 may have a material charging port for charging various materials into the preparation tank 1.

The preparation tank 1 may have a gas introduction port for introducing a gas into the inside of the tank.

The preparation tank 1 may have a gas discharge port for discharging a gas therein into the outside of the preparation tank 1.

A configuration of the production device for the composition for forming a non-photosensitive upper layer film is not limited to that shown in FIG. 2.

In addition, a cleaning nozzle (for example, a spray ball) may be disposed in an upper part of the preparation tank.

As the spray ball, a spray ball of a type in which the inside of a preparation tank can be uniformly cleaned by rotating the spray ball in a case where a cleaning liquid flows is preferable.

In a case where the concentration of the resin included in the cleaning liquid taken out from the production device is 10 ppm by mass or less and the cleaning is completed, the valve 7 (extraction valve) can be opened to discharge the cleaning liquid.

### Cleaning Liquid

The cleaning liquid is not particularly limited, but is preferably an organic solvent.

The cleaning liquid preferably includes, for example, a cleaning liquid including at least one organic solvent selected from the group consisting of a hydrocarbon-based solvent, a ketone-based solvent, an ester-based solvent, an alcohol-based solvent, an amide-based solvent, and an ether-based solvent, and more preferably includes the alcohol-based solvent. It is more preferable that the alcohol-based solvent is contained in an amount of 40% to 100% by mass with respect to all the solvents included in the cleaning liquid.

Specific examples of the alcohol-based solvent include 1-butanol, 2-butanol, 3-methyl-1-butanol, tert-butyl alcohol, 1-pentanol, 2-pentanol, 1-hexanol, 1-heptanol, 1-octanol, 2-hexanol, cyclopentanol, 2-heptanol, 2-octanol, 3-hexanol, 3-heptanol, 3-octanol, 4-octanol, and 4-methyl-2-pentanol (MIBC).

In addition, examples of the organic solvent that is preferable as the cleaning liquid include diisoamyl ether, decane, propylene glycol monomethyl ether acetate (PGMEA), propylene glycol monomethyl ether (PGME), and cyclohexanone.

The cleaning liquid particularly preferably includes at least 4-methyl-2-pentanol, and most preferably includes 4-methyl-2-pentanol in an amount of 40% to 100% by mass with respect to all the solvents included in the cleaning liquid.

A solubility parameter of the cleaning liquid is not particularly limited, but is preferably 15.0 to 25.5 MPa^{½}.

The solubility parameter (SP value) in the present invention is calculated by using the Fedors method described in “Properties of Polymers, 2^{nd} Edition, 1976”. A calculation formula used is shown below. In addition, an excerpt of the parameters of each substituent is shown in Table 1 below.

SP value (Fedors method) = [(Sum of cohesive energies of the respective substituents)/(Sum of volumes of the respective substituents)]^{0.5}

TABLE 1

| Substituent | Cohesive energy (J/mol) | Volume (cm³/mol) |
|---|---|---|
| CH₃ | 4,710 | 33.5 |
| CH₂ | 4,940 | 16.1 |
| CH | 3,430 | -1 |
| C | 1,470 | -19.2 |
| CH₂═ | 4,310 | 28.5 |
| ═CH— | 4,310 | 13.5 |
| ═C< | 4,310 | -5.5 |
| Ph | 31,940 | 71.4 |
| NH₂ | 12,560 | 19.2 |
| NH | 8,370 | 4.5 |
| N< | 4,190 | -9 |
| CN | 25,530 | 24 |
| OH | 29,800 | 10 |
| CHO | 21,350 | 22.3 |
| COOH | 27,630 | 28.5 |
| —O— | 3,350 | 3.8 |
| CO | 17,370 | 10.8 |
| COO | 18,000 | 18 |
| 5- or higher-membered ring | 1,050 | 16 |

The production device for the composition X_{A} for forming a non-photosensitive upper layer film is a production device used for producing the composition X_{B} for forming a non-photosensitive upper layer film containing a solvent S_{B} before producing the composition X_{A} for forming a non-photosensitive upper layer film, and |SP_{W} - SP_{B}|, an absolute value of a difference between a solubility parameter SP_{W} of the cleaning liquid and a solubility parameter SP_{B} of the solvent S_{B}, is preferably less than 1.0 MPa^{½}.

By setting |SP_{W} - SP_{B}| to less than 1.0 MPa^{½}, a cleaning liquid having a high affinity with the solvent S_{B} used in the composition X_{B} for forming a non-photosensitive upper layer film can be selected, and the removal of the resin in the production device using the cleaning liquid can be efficiently performed, whereby the concentration of the resin in the cleaning liquid taken out from the production device can be reduced by filtering the cleaning liquid which has cleaned the inside of the production device.

|SP_{W} - SP_{B}| is more preferably from 0.0 MPa^{½} to 0.6 MPa^{½}, still more preferably from 0.0 MPa^{½} to 0.5 MPa^{½}, particularly preferably from 0.0 MPa^{½} to 0.4 MPa^{½}, and most preferably from 0.0 MPa^{½} to 0.2 MPa^{½}.

In a case where the cleaning liquid or the solvent is a mixture (mixed solvent) composed of two or more kinds of compounds, the SP value is an SP value of the mixed solvent. In a case where n kinds of solvents are present in the mixed solvent, the SP value (SPₘᵢₓ) of the mixed solvent can be determined by Expression (1). It should be noted that n represents an integer of 2 or more, i represents an integer of 1 to n, SPᵢ represents an SP value of each solvent, and Xi represents a content (% by mass) of each solvent with respect to the total solvent.

### Expression 1

$${\text{SP}}_{\text{mix}} = {\sum }_{\text{i=1}}^{\text{n}} \left({\text{SP}}_{\text{i}} ⋅ \frac{{\text{X}}_{\text{i}}}{100}\right)$$

In the method for producing a composition X_{A} for forming a non-photosensitive upper layer film of the embodiment of the present invention, the cleaning of the production device may be performed using two or more kinds of cleaning liquids. That is, the composition of the cleaning liquid (the type of the solvent constituting the cleaning liquid and the content thereof) may be changed during the cleaning of the production device.

In the present invention, it is preferable that the cleaning of the production device is performed using at least two kinds of cleaning liquids, a first cleaning liquid and a second cleaning liquid,
the composition X_{A} for forming a non-photosensitive upper layer film contains a solvent S_{A},
   |SP_{W1} - SP_{B}|, an absolute value of the difference between the solubility parameter SP_{W1} of the first cleaning liquid and the solubility parameter SP_{B} of the solvent S_{B}, is less than 1.0 MPa^{½}, and
   |SP_{W2} - SP_{A}|, an absolute value of the difference between the solubility parameter SP_{W2} of the second cleaning liquid and the solubility parameter SP_{A} of the solvent S_{A}, is preferably less than 1.0 MPa^{½}.

By setting |SP_{W2} - SP_{A}| to less than 1.0 MPa^{½} in addition to setting |SP_{W1} - SP_{B}| to less than 1.0 MPa^{½}, a cleaning liquid having a high affinity with the solvent S_{A} used in the composition X_{A} for forming a non-photosensitive upper layer film can be selected, and the removal of the resin in the production device using the cleaning liquid can be efficiently performed.

|SP_{W1} - SP_{B}| is more preferably from 0.0 MPa^{½} to 0.6 MPa^{½}, still more preferably from 0.0 MPa^{½} to 0.5 MPa^{½}, particularly preferably from 0.0 MPa^{½} to 0.4 MPa^{½}, and most preferably from 0.0 MPa^{½} to 0.2 MPa^{½}.

|SP_{W2} - SP_{A}| is more preferably from 0.0 MPa^{½} to 0.6 MPa^{½}, still more preferably from 0.0 MPa^{½} to 0.5 MPa^{½}, particularly preferably from 0.0 MPa^{½} to 0.4 MPa^{½}, and most preferably from 0.0 MPa^{½} to 0.2 MPa^{½}.

### Production for Composition X_{A} for Forming Non-Photosensitive Upper Layer Film

In the present invention, in a case where the concentration of the resin in the cleaning liquid is 10 ppm by mass or less, the cleaning liquid can be discharged from the production device to produce the composition X_{A} for forming a non-photosensitive upper layer film.

The procedure for producing the composition X_{A} for forming a non-photosensitive upper layer film is not particularly limited, but examples thereof include a method in which various components constituting the composition X_{A} for forming a non-photosensitive upper layer film are added to a production device and mixed to produce the composition X_{A} for forming a non-photosensitive upper layer film.

The types of the components constituting the composition X_{A} for forming a non-photosensitive upper layer film added to the preparation tank of the production device are not particularly limited, and examples thereof include a resin and a solvent. These components will be described later.

The procedure for charging the above-mentioned components into the preparation tank is not particularly limited.

Examples thereof include a method of charging various components from a material charging port of the preparation tank. In a case of charging the various components, the components may be charged sequentially or collectively. In a case of charging one kind of component, the component may be charged a plurality of times.

In addition, in a case where the respective components are sequentially charged into the preparation tank, the charging order is not particularly limited.

In a case where the components other than the solvent are charged into the preparation tank, the components may be charged into the preparation tank as a solution in which the components are dissolved in the solvent. At that time, in order to remove an insoluble matter in the solution, the solution may be filtered with a filter and then charged into the preparation tank.

In addition, in a case where the solvent is charged into the preparation tank, the solvent may be filtered and then charged into the preparation tank. Examples of the filter used above include filters described above.

Furthermore, in a case where various components are charged into the preparation tank, a liquid feeding pump may be used.

In the production of the composition X_{A} for forming a non-photosensitive upper layer film, it is preferable to carry out stirring and mixing of the components constituting the composition X_{A} for forming a non-photosensitive upper layer film.

A method for performing the stirring and mixing is not particularly limited, but is preferably carried out with by the above-mentioned stirrer. In a case of performing the stirring and mixing, it is preferable to perform the stirring in consideration of a shape and a size of the stirring blade, an installation location, a stirring rotation speed, and the like such that the liquid is sufficiently stirred.

The temperature of the mixture including the components constituting the composition X_{A} for forming a non-photosensitive upper layer film to be mixed by stirring is not particularly limited, but is preferably 15° C. to 32° C., and more preferably 20° C. to 24° C.

In addition, in a case of performing the stirring and mixing, the temperature of the mixture is preferably kept constant, and is preferably within ±10° C., more preferably within ±5° C., and still more preferably within ±1° C. from a set temperature.

A stirring and mixing time is not particularly limited, but is preferably 1 to 48 hours, and more preferably 15 to 24 hours from the viewpoint of a balance of the uniformity of the obtained composition X_{A} for forming a non-photosensitive upper layer film and the productivity.

A rotation speed of the stirring blade in the stirring and mixing is not particularly limited, but is preferably 20 to 500 rotations per minute (rpm), more preferably 40 to 350 rpm, and still more preferably 50 to 300 rpm.

Furthermore, in a case of stopping the stirring and mixing, it is preferable to confirm that various components are dissolved in the solvent.

During the stirring and mixing, ultrasonic waves may be applied to the mixture.

As shown in FIG. 2, the composition X_{A} for forming a non-photosensitive upper layer film produced in the preparation tank 1 may be accommodated in a predetermined container 9 from a discharge nozzle not shown.

The filling speed in a case of filling the container with the composition X_{A} for forming a non-photosensitive upper layer film is not particularly limited, but is preferably 0.3 to 3.0 L/min, more preferably 0.4 to 2.0 L/min, and still more preferably 0.5 to 1.5 L/min in a case of a container having a capacity of 0.75 L or more and less than 5 L.

A plurality of discharge nozzles may be arranged in parallel and filling may be performed at the same time in order to improve a filling efficiency.

The container is not particularly limited, and examples thereof include a bloom-treated glass container and a container in which a liquid contact part is treated to be a fluororesin.

In a case where the composition X_{A} for forming a non-photosensitive upper layer film is accommodated in the container, a space in the container (a region in the container not occupied by the composition X_{A} for forming a non-photosensitive upper layer film) may be substituted with a predetermined gas. The gas is preferably a gas which is inert or non-reactive with respect to the composition X_{A} for forming a non-photosensitive upper layer film, and specific examples thereof include nitrogen and rare gases such as helium and argon.

Furthermore, a degassing treatment for removing the dissolved gas in the composition X_{A} for forming a non-photosensitive upper layer film may be carried out before accommodating the composition X_{A} for forming a non-photosensitive upper layer film in the container. Examples of the degassing method include an ultrasonic treatment and a defoaming treatment.

### Composition X_{A} for Forming Non-Photosensitive Upper Layer Film

The composition X_{A} for forming a non-photosensitive upper layer film is not particularly limited as long as it is a composition which can be used for forming a non-photosensitive upper layer film disposed on a photosensitive resist film. The composition X_{A} for forming a non-photosensitive upper layer film is a composition of which properties do not change even in a case of being irradiated with light, and is typically a composition which does not substantially contain a photoacid generator. The expression that the photoacid generator is not substantially contained means that the content of the photoacid generator is 5% by mass or less with respect to the total solid content in the composition, and the content of the photoacid generator is preferably 2% by mass or less, and more preferably 0% by mass (that is, the photoacid generator is not contained). Moreover, in the present specification, the solid content means components other than the solvent. Even in a case where the properties of the components are liquid, they are treated as solid contents. The total solid content means a total of all the solid contents.

### Resin

The composition X_{A} for forming a non-photosensitive upper layer film preferably contains a resin.

The composition X_{A} for forming a non-photosensitive upper layer film preferably contains a resin having a repeating unit represented by General Formula (I) (also referred to as a “resin X”).

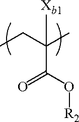

In General Formula (I), X_{b1} represents a hydrogen atom, an alkyl group, a cyano group, or a halogen atom, and R₂ represents an organic group.

In General Formula (I), X_{b1} represents a hydrogen atom, an alkyl group, a cyano group, or a halogen atom, and preferably represents the hydrogen atom or the alkyl group, and more preferably represents the alkyl group. The number of carbon atoms in the alkyl group in a case where X_{b1} represents the alkyl group is not particularly limited, and for example, an alkyl group having 1 to 5 carbon atoms is preferable. The alkyl group may be linear or branched. The alkyl group may have a substituent.

In General Formula (I), the organic group represented by R₂ is preferably an organic group having 1 to 30 carbon atoms, and examples thereof include an alkyl group, a cycloalkyl group, an aryl group, an aralkyl group, an alkenyl group, and an alkylamino group. These groups may further have a substituent. Examples of the substituent which can be further contained include an alkyl group (preferably having 1 to 4 carbon atoms), a halogen atom, a hydroxy group, an alkoxy group (preferably having 1 to 4 carbon atoms), a carboxy group, and an alkoxycarbonyl group (preferably having 2 to 6 carbon atoms).

The resin X preferably has an acid group. In this case, the resin X may have an acid group in the repeating unit represented by General Formula (I) (that is, at least one of X_{b1} or R₂), or may have an acid group in a repeating unit other than the repeating unit represented by General Formula (I).

Examples of the acid group include a carboxy group, a phenolic hydroxyl group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

The acid group is preferably at least one selected from the group consisting of a carboxy group, a fluorinated alcohol group, a sulfonic acid group, and a sulfonamide group. The fluorinated alcohol group is preferably a group obtained by substituting at least one of the hydrogen atoms bonded to the carbon atom of the hydroxyalkyl group with a fluorine atom, and particularly preferably a hexafluoroisopropanol group (—C(CF₃)₂OH).

The resin X preferably has a fluorine-containing group.

The fluorine-containing group may be a fluorine atom or an organic group having a fluorine atom as a substituent. The organic group in the organic group having a fluorine atom as a substituent is not particularly limited, and is preferably an organic group having 1 to 15 carbon atoms, and more preferably an organic group having 1 to 10 carbon atoms. Examples of the organic group include an alkyl group, a cycloalkyl group, an aryl group, an aralkyl group, and an alkenyl group. These groups may further have a substituent.

The resin X preferably has no acid-decomposable group.

The acid-decomposable group refers to a group that decomposes by the action of an acid to generate a polar group. The acid-decomposable group typically has a structure in which a polar group is protected by a group that leaves by the action of an acid (leaving group). Examples of the polar group include an alkali-soluble group, for example, an acidic group such as a carboxyl group, a phenolic hydroxyl group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group, and an alcoholic hydroxyl group.

The resin X may have other repeating units in addition to the repeating unit represented by General Formula (I).

Specific examples of the monomer corresponding to the repeating unit which may be contained in the resin X are shown below, but the resin X is not limited thereto.

Hereinafter, TMS represents a trimethylsilyl group.

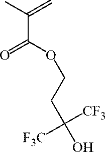 [SMILES: C=C(C)C(=O)OCCC(O)(C(F)(F)F)C(F)(F)F]

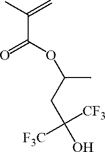 [SMILES: C=C(C)C(=O)OC(C)CC(O)(C(F)(F)F)C(F)(F)F]

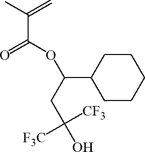 [SMILES: C=C(C)C(=O)OC(CC(O)(C(F)(F)F)C(F)(F)F)C1CCCCC1]

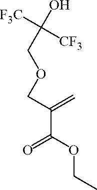 [SMILES: C=C(COCC(O)(C(F)(F)F)C(F)(F)F)C(=O)OCC]

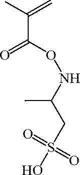

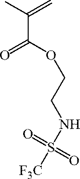 [SMILES: C=C(C)C(=O)OCCNS(=O)(=O)C(F)(F)F]

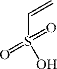

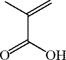

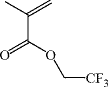

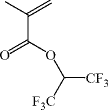

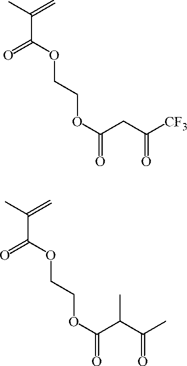 [SMILES: C=C(C)C(=O)OCCOC(=O)CC(=O)C(F)(F)F ; C=C(C)C(=O)OCCOC(=O)C(C)C(C)=O]

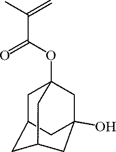 [SMILES: C=C(C)C(=O)OC12CC3CC(CC(O)(C3)C1)C2]

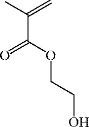

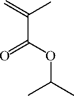

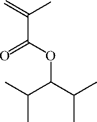

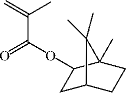 [SMILES: C=C(C)C(=O)OC1CC2CCC1(C)C2(C)C]

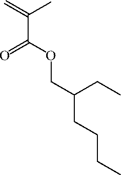

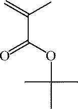

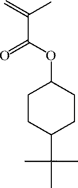 [SMILES: C=C(C)C(=O)OC1CCC(C(C)(C)C)CC1]

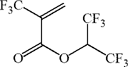 [SMILES: C=C(C(=O)OC(C(F)(F)F)C(F)(F)F)C(F)(F)F]

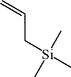

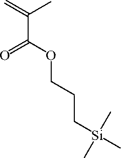

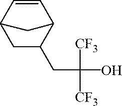 [SMILES: OC(CC1CC2C=CC1C2)(C(F)(F)F)C(F)(F)F]

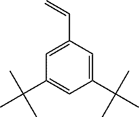 [SMILES: C=Cc1cc(C(C)(C)C)cc(C(C)(C)C)c1]

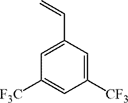 [SMILES: C=Cc1cc(C(F)(F)F)cc(C(F)(F)F)c1]

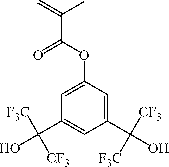 [SMILES: C=C(C)C(=O)Oc1cc(C(O)(C(F)(F)F)C(F)(F)F)cc(C(O)(C(F)(F)F)C(F)(F)F)c1]

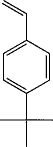

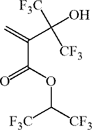 [SMILES: C=C(C(=O)OC(C(F)(F)F)C(F)(F)F)C(O)(C(F)(F)F)C(F)(F)F]

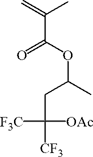 [SMILES: C=C(C)C(=O)OC(C)CC(OC(C)=O)(C(F)(F)F)C(F)(F)F]

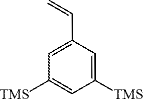 [SMILES: C=Cc1cc([Si](C)(C)C)cc([Si](C)(C)C)c1]

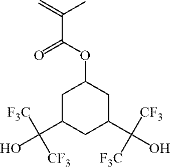 [SMILES: C=C(C)C(=O)OC1CC(C(O)(C(F)(F)F)C(F)(F)F)CC(C(O)(C(F)(F)F)C(F)(F)F)C1]

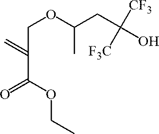 [SMILES: C=C(COC(C)CC(O)(C(F)(F)F)C(F)(F)F)C(=O)OCC]

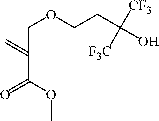 [SMILES: C=C(COCCC(O)(C(F)(F)F)C(F)(F)F)C(=O)OC]

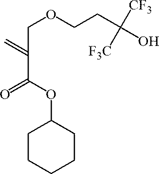 [SMILES: C=C(COCCC(O)(C(F)(F)F)C(F)(F)F)C(=O)OC1CCCCC1]

The resin X may have only one kind of repeating unit represented by General Formula (I), or may have two or more kinds of repeating units.

In addition, the content of the repeating unit represented by General Formula (I) in the resin X is preferably 60% to 100% by mole, more preferably 70% to 100% by mole, and still more preferably 80% to 100% by mole with respect to all the repeating units of the resin X.

The resin X can be synthesized in accordance with an ordinary method (for example, radical polymerization). Examples of the general synthesis method include a batch polymerization method of dissolving monomer species and a polymerization initiator in a solvent and heating the solution, thereby carrying out the polymerization, and a dropwise-addition polymerization method of adding dropwise a solution containing monomer species and a polymerization initiator to a heated solvent for 1 to 10 hours, with the dropwise-addition polymerization method being preferable.

The weight-average molecular weight (Mw) of the resin X is preferably 1,000 to 200,000, more preferably 3,000 to 20,000, and most preferably 5,000 to 15,000, as a value expressed in terms of polystyrene by a GPC method.

The dispersity (molecular weight distribution) of the resin X is usually 1 to 5, preferably 1 to 3, more preferably 1.2 to 3.0, and particularly preferably 1.2 to 2.0.

The resin contained in the composition X_{A} for forming a non-photosensitive upper layer film may be one kind or two or more kinds.

The content of the resin in the composition X_{A} for forming a non-photosensitive upper layer film is preferably 50% to 100% by mass, and more preferably 60% to 100% by mass with respect to the total solid content of the composition X_{A} for forming a non-photosensitive upper layer film.

In addition, the content of the resin X with respect to the total amount of the resin included in the composition X_{A} for forming a non-photosensitive upper layer film is preferably 60% to 100% by mass, more preferably 80% to 100% by mass, and still more preferably 100% by mass.

### Other Components

The composition X_{A} for forming a non-photosensitive upper layer film can include other components, in addition to the resin.

The composition X_{A} for forming a non-photosensitive upper layer film may further contain at least one compound selected from the group consisting of (A1) a basic compound or base generator, or a (A2) a compound containing a bond or group selected from the group consisting of an ether bond, a thioether bond, a hydroxyl group, a thiol group, a carbonyl bond, and an ester bond.

With regard to specific examples and preferred examples of the compounds, preferred ranges of the content of the composition X_{A} for forming a non-photosensitive upper layer film with respect to the total solid content, and the like, the content described in paragraphs [0141] to [0256] of WO2016/136596A can be incorporated.

### Surfactant

The composition X_{A} for forming a non-photosensitive upper layer film may further contain a surfactant.

The surfactant is not particularly limited, and any of an anionic surfactant, a cationic surfactant, and a nonionic surfactant can be used.

The composition X_{A} for forming a non-photosensitive upper layer film may or may not include a surfactant, but in a case where the composition X_{A} includes a surfactant, the content of the surfactant is preferably 0.001% to 20% by mass, and more preferably 0.01% to 10% by mass with respect to the total solid content of the composition X_{A} for forming a non-photosensitive upper layer film.

The surfactant may be used alone or in combination of two or more kinds thereof.

As the surfactant, for example, one selected from an alkyl cation-based surfactant, an amide-type quaternary cation-based surfactant, an ester type quaternary cation-based surfactant, an amine oxide-based surfactant, a betaine-based surfactant, an alkoxylate-based surfactant, a fatty acid ester-based surfactant, an amide-based surfactant, an alcohol-based surfactant, an ethylenediamine-based surfactant, and a fluorine-based and/or silicon-based surfactant (a fluorine-based surfactant, a silicon-based surfactant, or a surfactant having both of a fluorine atom and a silicon atom) can be suitably used.

Specific examples of the surfactant include polyoxyethylene alkyl ethers such as polyoxyethylene lauryl ether, polyoxyethylene stearyl ether, polyoxyethylene cetyl ether, and polyoxyethylene oleyl ether; polyoxyethylene alkylallyl ethers such as polyoxyethylene octylphenol ether and polyoxyethylene nonylphenol ether; polyoxyethylene/polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; surfactants such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; and commercially available surfactants mentioned later.

Examples of the commercially available surfactants that can be used include fluorine-based surfactants or silicon-based surfactants such as EFTOP EF301 and EF303 (manufactured by Shin-Akita Kasei K. K.), FLORAD FC430, 431, and 4430 (manufactured by Sumitomo 3M Inc.), MEGAFAC F171, F173, F176, F189, F113, F110, F177, F120, and R08 (manufactured by DIC Corp.), SURFLON S-382, SC101, 102, 103, 104, 105, and 106 (manufactured by Asahi Glass Co., Ltd.), TROYSOL S-366 (manufactured by Troy Chemical Corp.), GF-300 and GF-150 (manufactured by Toagosei Chemical Industry Co., Ltd.), SURFLON S-393 (manufactured by Seimi Chemical Co., Ltd.), EFTOP EF 121, EF122A, EF122B, RF122C, EF125M, EF135M, EF351, EF352, EF801, EF802, and EF601 (manufactured by JEMCO Inc.), PF636, PF656, PF6320, and PF6520 (manufactured by OMNOVA Solutions Inc.), and FTX-204G, 208G, 218G, 230G, 204D, 208D, 212D, 218, and 222D (manufactured by NEOS Co., Ltd.). In addition, Polysiloxane Polymer KP-341 (manufactured by Shin-Etsu Chemical Co., Ltd.) can also be used as the silicon-based surfactant.

### Solvent

The composition X_{A} for forming a non-photosensitive upper layer film preferably contains a solvent.

In order to form a good pattern without dissolving the photosensitive resist film, the composition X_{A} for forming a non-photosensitive upper layer film preferably contains a solvent that does not dissolve the photosensitive resist film, and in a case where development is performed using a developer (organic developer) containing an organic solvent, the composition X_{A} for forming a non-photosensitive upper layer film more preferably contains a solvent different from the organic developer.

In addition, from the viewpoint of the prevention of elution into an immersion liquid, low solubility in an immersion liquid is preferred, and low solubility in water is more preferable. In the present specification, the description of “having low solubility in an immersion liquid” represents insolubility in an immersion liquid. Similarly, “having low solubility in water” means insolubility in water. Further, from the viewpoints of volatility and coatability, the boiling point of the solvent is preferably 90° C. to 200° C.

The description of “having low solubility in an immersion liquid” indicates that in an example of the solubility in water, in a case where the composition X_{A} for forming a non-photosensitive upper layer film is applied onto a silicon wafer and dried to form a film, and then the film is immersed in pure water at 23° C. for 10 minutes, the decrease rate in the film thickness after drying is within 3% of the initial film thickness (typically 50 nm).

From the viewpoint of uniformly applying the composition X_{A} for forming a non-photosensitive upper layer film, a solvent such that the concentration of solid contents of the composition X_{A} for forming a non-photosensitive upper layer film is preferably 0.01% to 20% by mass, more preferably 0.1% to 15% by mass, and most preferably 1% to 10% by mass is used.

The solvent is preferably a solvent that dissolves the resin contained in the composition X_{A} for forming a non-photosensitive upper layer film and does not dissolve the photosensitive resist film as described above, and suitable examples thereof include an alcohol-based solvent, an ether-based solvent, an ester-based solvent, a fluorine-based solvent, and a hydrocarbon-based solvent.

The composition X_{A} for forming a non-photosensitive upper layer film preferably contains at least one of the alcohol-based solvent or the ether-based solvent. The viscosity of the solvent is preferably 5 centipoises (cP) or less, more preferably 3 cP or less, still more preferably 2 cP or less, and particularly preferably 1 cP or less.

From the viewpoint of coatability, the alcohol-based solvent is preferably a monohydric alcohol, and more preferably a monohydric alcohol having 4 to 8 carbon atoms. As the monohydric alcohol having 4 to 8 carbon atoms, a linear, branched, or cyclic alcohol may be used, but a linear or branched alcohol is preferable. Examples of such an alcohol-based solvent include those described in paragraph [0052] of WO2016/136596A.

Examples of the ether-based solvent include, in addition to the glycol ether-based solvents, dioxane, tetrahydrofuran, and isoamyl ether. Among the ether-based solvents, an ether-based solvent having a branched structure is preferable.

Examples of the ester-based solvent include those described in paragraph [0052] of WO2016/136596A. Among the ester-based solvents, an ester-based solvent having a branched structure is preferable.

Examples of the fluorine-based solvent include those described in paragraph [0053] of WO2016/136596A. Among these, a fluorinated alcohol or a fluorinated hydrocarbon-based solvent can be suitably used.

Examples of the hydrocarbon-based solvent include those described in paragraph [0053] of WO2016/136596A.

These solvents are used alone or as a mixture of a plurality of kinds thereof.

In a case of mixing other solvents with the solvents, the mixing ratio is usually 0% to 30% by mass, preferably 0% to 20% by mass, and more preferably 0% to 10% by mass, with the total amount of solvents of the composition X_{A} for forming a non-photosensitive upper layer film. By mixing a solvent other than the above-mentioned solvents, the solubility for the photosensitive resist film, the solubility of the resin in the composition X_{A} for forming a non-photosensitive upper layer film, the elution characteristics from the photosensitive resist film, or the like can be appropriately adjusted.

A transmittance of the ArF excimer laser light of the non-photosensitive upper layer film having a film thickness of 30 nm formed by using the composition X_{A} for forming a non-photosensitive upper layer film is preferably 80% or more, more preferably 90% or more, and still more preferably 95% or more.

### Composition X_{B} for Forming Non-Photosensitive Upper Layer Film

A detailed description of the composition X_{B} for forming a non-photosensitive upper layer film (components which are preferably contained in the composition, components which may be contained in the composition, preferred ranges of contents thereof, and the like) is the same as the composition X_{A} for forming a non-photosensitive upper layer film. The composition X_{B} for forming a non-photosensitive upper layer film may be the same composition as the composition X_{A} for forming a non-photosensitive upper layer film, or may be a composition different from the composition X_{A} for forming a non-photosensitive upper layer film (a composition having a different type or content of the component contained therein).

### Photosensitive Resist Film

The photosensitive resist film can be formed using a photosensitive resist composition.

### Resin (A)

The photosensitive resist composition may be either a negative tone resist composition or a positive tone resist composition, and typically contains a resin of which polarity increases by the action of an acid.

The resin of which polarity increases by the action of an acid (hereinafter also referred to as a “resin (A)”) is preferably a resin (hereinafter also referred to as an “acid-decomposable resin” or an “acid-decomposable resin (A)”) having a group (acid-decomposable group) that decomposes by the action of an acid to generate a polar group at either the main chain or the side chain of the resin, or at both the main chain and the side chain.

Examples of the polar group in the acid-decomposable group typically include acid groups, specifically a group having a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

Preferred examples of the polar group include a carboxylic acid group, a fluorinated alcohol group (preferably hexafluoroisopropanol), and a sulfonic acid group.

A preferred group capable of decomposing by an acid (acid-decomposable group) is a group obtained by substituting a hydrogen atom of these polar groups with a group capable of leaving with an acid.

Examples of the group capable of leaving by an acid include -C(R₃₆)(R₃₇)(R₃₈), -C(R₃₆)(R₃₇)(OR₃₉), and -C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

As the acid-decomposable group, a cumyl ester group, an enol ester group, an acetal ester group, a tertiary alkyl ester group, or the like is preferable. As the acid-decomposable group, the tertiary alkyl ester group is more preferable.

The resin (A) is preferably a resin containing at least one selected from a group of repeating units having partial structures represented by General Formulae (pI) to (pV) and a repeating unit represented by General Formulae (II-AB).

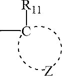

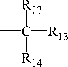

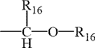

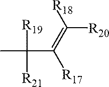

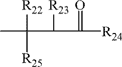

In General Formulae (pI) to (pV),

R₁₁represents a methyl group, an ethyl group, an n-propyl group, an isopropyl group, an n-butyl group, an isobutyl group, or a sec-butyl group, and Z represents an atomic group which is necessary for forming a cycloalkyl group together with carbon atoms.

R₁₂ to R₁₆ each independently represent a linear or branched alkyl group or cycloalkyl group, having 1 to 4 carbon atoms. It should be noted that at least one of R₁₂, R₁₃, or R₁₄, or either R₁₅ or R₁₆ represents a cycloalkyl group.

R₁₇ to R₂₁ each independently represent a hydrogen atom, a linear or branched alkyl group having 1 to 4 carbon atoms, or a cycloalkyl group. It should be noted that at least one of R₁₇, ..., or R₂₁ represents a cycloalkyl group. In addition, either R₁₉ or R₂₁ is a linear or branched alkyl group, or cycloalkyl group, having 1 to 4 carbon atoms.

R₂₂ to R₂₅ each independently represent a hydrogen atom, a linear or branched alkyl group, or a cycloalkyl group, having 1 to 4 carbon atoms. It should be noted that at least one of R₂₂, ..., or R₂₅ represents a cycloalkyl group. In addition, R₂₃ and R₂₄ may be bonded to each other to form a ring.

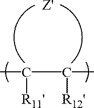

In General Formula (II-AB),
R₁₁′ and R₁₂′ each independently represent a hydrogen atom, a cyano group, a halogen atom, or an alkyl group.
Z′ represents an atomic group including two carbon atoms (C-C) bonded to each other for forming an alicyclic structure.

Furthermore, General Formula (II-AB) is more preferably General Formula (II-AB1) or General Formula (II-AB2).

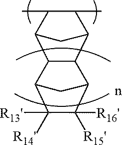

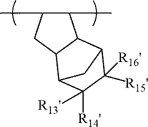

In Formulae (II-AB1) and (II-AB2),

R₁₃′ to R₁₆′ each independently a hydrogen atom, a halogen atom, a cyano group, —COOH, -COOR₅, a group that decomposes by the action of an acid, -C(=O)-X-A′-R_{I7}′, an alkyl group, or a cycloalkyl group. At least two of Rc₁₃′, ..., or R_{C16}′may be bonded to each other to form a ring.

Here, R₅ represents an alkyl group, a cycloalkyl group, or a group having a lactone structure.

X represents an oxygen atom, a sulfur atom, —NH—, —NHSO₂—, or —NHSO₂NH—.

A′ represents a single bond or a divalent linking group.

R₁₇′ represents —COOH, —COOR₅, —CN, a hydroxyl group, an alkoxy group, -CO-NH-R₆, -CO-NH-SO₂-R₆, or a group having a lactone structure.

R₆ represents an alkyl group or a cycloalkyl group.

n represents 0 or 1.

In General Formulae (pI) to (pV), the alkyl group in each of R₁₂ to R₂₅ represents a linear or branched alkyl group having 1 to 4 carbon atoms.

The cycloalkyl group in each of R₁₁ to R₂₅ or the cycloalkyl group formed by Z together with carbon atoms may be monocyclic or polycyclic. Specific examples thereof include a group having 5 or more carbon atoms and having a monocyclo, bicyclo, tricyclo, or tetracyclo structure. These cycloalkyl groups preferably have 6 to 30 carbon atoms, and particularly preferably 7 to 25 carbon atoms. These cycloalkyl groups may have a substituent.

Preferred examples of the cycloalkyl group include an adamantyl group, a noradamantyl group, a decalin residue, a tricyclodecanyl group, a tetracyclododecanyl group, a norbornyl group, cedrol group, a cyclopentyl group, a cyclohexyl group, a cycloheptyl group, a cyclooctyl group, a cyclodecanyl group, and a cyclododecanyl group. More preferred examples thereof include an adamantyl group, a norbornyl group, a cyclohexyl group, a cyclopentyl group, a tetracyclododecanyl group, and a tricyclodecanyl group.

Examples of a substituent which may further be included in these alkyl groups and cycloalkyl groups include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). Examples of the substituent which may further be included in the alkyl group, the alkoxy group, the alkoxycarbonyl group, or the like include a hydroxyl group, a halogen atom, and an alkoxy group.

The structures represented by General Formulae (pI) to (pV) in the resin can be used in the protection of the polar group. Examples of the polar group include various groups that have been known in the technical field.

Specific examples of the structure include a structure in which a hydrogen atom in a carboxylic acid group, a sulfonic acid group, a phenol group, or a thiol group is substituted with a structure represented by any of General Formulae (pI) to (pV), with a structure in which a hydrogen atom in a carboxylic acid group or a sulfonic acid group is substituted with a structure represented by any of General Formulae (pI) to (pV) being preferable.

As the repeating unit having a polar group protected by the structure represented by one of General Formulae (pI) to (pV), a repeating unit represented by General Formula (pA) is preferable.

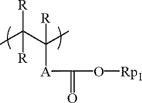

Here, R represents a hydrogen atom, a halogen atom, or a linear or branched alkyl group having 1 to 4 carbon atoms. A plurality of R’s may be the same as or different from each other.

A is a single bond, or one group or a combination of two or more groups selected from the group consisting of an alkylene group, an ether group, a thioether group, a carbonyl group, an ester group, an amide group, a sulfonamide group, a urethane group, or a urea group, with the single bond being preferable.

Rp₁ is a group of any of Formulae (pI) to (pV).

The repeating unit represented by General Formula (pA) is particularly preferably a repeating unit derived from 2-alkyl-2-adamantyl (meth)acrylate or dialkyl (1-adamantyl)methyl (meth)acrylate.

Specific examples of the repeating unit represented by General Formula (pA) include those described in paragraphs [0313] and [0314] of WO2016/136596A.

Examples of the halogen atom in each of R₁₁′ and R₁₂′ in General Formula (II-AB) include a chlorine atom, a bromine atom, a fluorine atom, and an iodine atom.

Examples of the alkyl group in each of R₁₁′ and R₁₂′ include a linear or branched alkyl group having 1 to 10 carbon atoms.

The atomic group for forming the alicyclic structure of Z′ is an atomic group that forms, in the resin, a repeating unit of an alicyclic hydrocarbon which may have a substituent, and among these, an atomic group for forming a bridged alicyclic structure that forms a repeating unit of a bridged alicyclic hydrocarbon is preferable.

Examples of the skeleton of the alicyclic hydrocarbons to be formed include the same skeletons as the alicyclic hydrocarbon groups of R₁₂ to R₂₅ in General Formulae (pI) to (pV).

The skeleton of the alicyclic hydrocarbon may have a substituent. Examples of such a substituent include R₁₃′ to R₁₆′ in General Formula (II-AB1) or (II-AB2).

The resin (A) is preferably a resin having a repeating unit having an acid-decomposable group, and the acid-decomposable group is included in, for example, at least one of repeating units having the partial structures represented by General Formulae (pI) to (pV), the repeating unit represented by General Formula (II-AB), or a repeating unit of the following copolymerization component. The acid-decomposable group is preferably included in the repeating units having partial structures represented by General Formula (pI) to General Formula (pV).

The repeating unit having an acid-decomposable group contained in the resin (A) may be used alone or in combination of two or more kinds thereof.

The resin (A) preferably contains a repeating unit having a lactone structure or a sultone (cyclic sulfonic acid ester) structure.

As the lactone group or the sultone group, any group may be used as long as it has a lactone structure or a sultone structure, but the structure is preferably a 5- to 7-membered ring lactone structure or sultone structure, and preferably a 5- to 7-membered ring lactone structure or sultone structure to which another ring structure is fused in the form of forming a bicyclo structure or a spiro structure. The resin (A) still more preferably has a repeating unit having a lactone structure or a sultone structure represented by any of General Formulae (LC1-1) to (LC1-17), (SL1-1), and (SL1-2). In addition, a lactone structure or sultone structure may be bonded directly to the main chain. The lactone structures or the sultone structures are preferably (LC1-1), (LC1-4), (LC1-5), and (LC1-8), and more preferably (LC1-4). By using such a specific lactone structure or sultone structure, LWR and development defects are relieved.

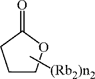

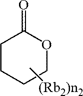

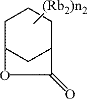

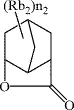

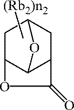

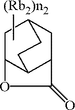

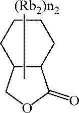

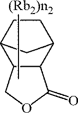

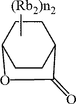

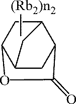

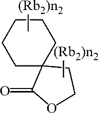

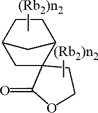

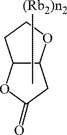

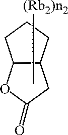

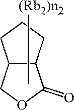

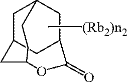

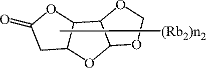

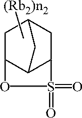

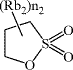

The lactone structure moiety or the sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. Among those, an alkyl group having 1 to 4 carbon atoms, a cyano group, and an acid-decomposable group are more preferable. n2 represents an integer of 0 to 4. In a case where n₂ is 2 or more, the substituents (Rb₂) which are present in plurality may be the same as or different from each other, and further, the substituents (Rb₂) which are present in plurality may be bonded to each other to form a ring.

The resin (A) preferably has a repeating unit containing an organic group having a polar group, in particular, a repeating unit having an alicyclic hydrocarbon structure substituted with a polar group. As a result of this, the adhesiveness to a substrate and the affinity for a developer are improved. The alicyclic hydrocarbon structure in the alicyclic hydrocarbon structure substituted with a polar group is preferably an adamantyl group, a diamantyl group, or a norbornane group. As the polar group, a hydroxyl group or a cyano group is preferable.

As the alicyclic hydrocarbon structure substituted with a polar group, partial structures represented by General Formulae (VIIa) to (VIId) are preferable.

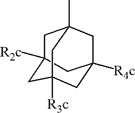

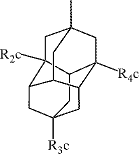

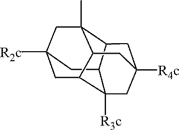

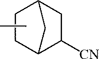

In General Formulae (VIIa) to (VIIc),

R_{2c} to R_{4c} each independently represent a hydrogen atom, a hydroxyl group, or a cyano group. It should be noted that at least one of R_{2c}, ..., or R_{4c} represents a hydroxyl group or a cyano group. It is preferable that one or two of R_{2c} to R_{4c} are hydroxyl groups, and the rest are hydrogen atoms.

In General Formula (VIIa), it is more preferable that two of R2_{c} to R4_{c} are hydroxyl groups and the remaining is a hydrogen atom.

Examples of the repeating units having the groups represented by General Formulae (VIIa) to (VIId) include repeating units in which at least one of R₁₃′, ..., or R₁₆′ in General Formula (II-AB1) or (II-AB2) has a group represented by General Formula (VII) (for example, R₅ in -COOR₅ represents a group represented by any of General Formulae (VIIa) to (VIId)) or a repeating unit represented by any of General Formulae (AIIa) to (AIId).

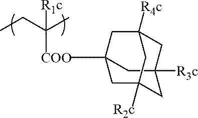

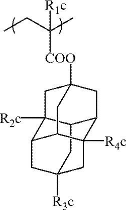

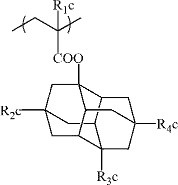

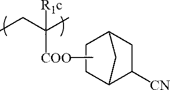

In General Formulae (AIIa) to (AIId),

R_{1c} represents a hydrogen atom, a methyl group, a trifluoromethyl group, or a hydroxymethyl group.

R_{2C} to R_{4c} have the same definitions as R_{2c} to R_{4c} in General Formulae (VIIa) to (VIIc), respectively.

Specific examples of the repeating unit having a structure represented by any of General Formulae (AIIa) to (AIId) are given below, but the present invention is not limited thereto.

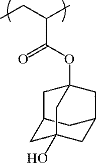

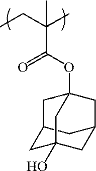

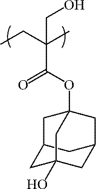

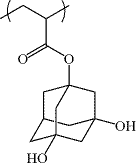

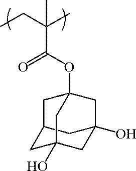

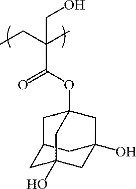

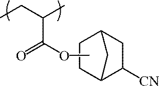

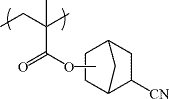

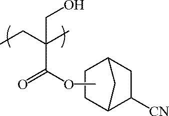

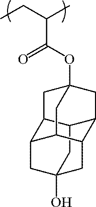

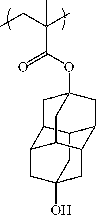

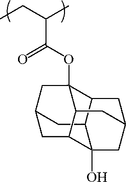

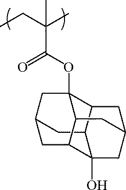

The weight-average molecular weight of the resin (A) is preferably 1,000 to 200,000, more preferably 1,000 to 20,000, and still more preferably 1,000 to 15,000, as a value expressed in terms of polystyrene according to a GPC method.

The dispersity (molecular weight distribution) of the resin (A) is usually 1 to 5, and a dispersity in a range of preferably 1 to 3, more preferably 1.2 to 3.0, and particularly preferably 1.2 to 2.0 is used.

The content of the resin (A) is preferably 50% to 99.9% by mass, and more preferably 60% to 99.0% by mass in the total solid content of the photosensitive resist composition.

In addition, the resin (A) may be used alone or in combination of a plurality thereof.

### <Photoacid Generator>

The photosensitive resist composition typically contains a compound that generates an acid upon irradiation with actinic rays or radiation (also referred to as a “photoacid generator” or a “compound (B)” ).

The compound (B) may be in a form of a low-molecular-weight compound or a form incorporated into a part of a polymer. In addition, a combination of the form of a low-molecular-weight compound and the form incorporated into a part of a polymer may also be used.

In a case where the compound (B) of the present invention is in the form of the low-molecular-weight compound, the molecular weight is preferably 3,000 or less, more preferably 2,000 or less, and still more preferably 1,000 or less.

In a case where the compound (B) is in the form incorporated into a part of the polymer, it may be incorporated into a part of the above-mentioned acid-decomposable resin or into a resin different from the acid-decomposable resin.

In the present invention, the photoacid generator (B) is preferably in the form of a low-molecular-weight compound.

As such a compound (B), a photoacid generator which is appropriately selected from known compounds capable of generating an acid upon irradiation with actinic rays or radiation which are used for a photoinitiator for cationic photopolymerization, a photoinitiator for radical photopolymerization, a photodecoloring agent for dyes, a photodiscoloring agent, a microresist, or the like, and a mixture thereof can be used.

Examples of the photoacid generator include a diazonium salt, a phosphonium salt, a sulfonium salt, an iodonium salt, imidosulfonate, oxime sulfonate, diazodisulfone, disulfone, and o-nitrobenzyl sulfonate.

In addition, a compound in which a group or compound capable of generating an acid upon irradiation with actinic rays or radiation is introduced into the main or side chain of the polymer, for example, the compounds described in US3849137A, GE3914407A, JP1988-26653A (JP-S63-26653A), JP1980-164824A (JPS55-164824A), JP1987-69263A (JP-S62-69263A), JP1988-146038A (JP-S63-146038A), JP1988-163452A (JP-S63-163452A), JP1987-153853A (JP-S62-153853A), JP1988-146029A (JP-S63-146029A), and the like can be used.

In addition, the compounds capable of generating an acid by light described in US3779778A, EP126712B, and the like can also be used.

As the compound (B), a compound that generates an acid having a cyclic structure upon irradiation with actinic rays or radiation is preferable. As the cyclic structure, a monocyclic or polycyclic alicyclic group is preferable, and a polycyclic alicyclic group is more preferable. It is preferable that carbonyl carbon is not included as a carbon atom constituting the ring skeleton of the alicyclic group.

Suitable examples of the compound (B) include a compound (specific acid generator) capable of generating an acid upon irradiation with actinic rays or radiation, represented by General Formula (3).

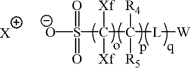

### Anion

In General Formula (3),

Xfs each independently represent a fluorine atom or an alkyl group substituted with at least one fluorine atom.

R₄ and R₅ each independently represent a hydrogen atom, a fluorine atom, an alkyl group, or an alkyl group substituted with at least one fluorine atom, and in a case where a plurality of R₄′s and R₅′s are present, they may be the same as or different from each other.

L represents a divalent linking group, and in a case where L’s are present in plurality, they may be the same as or different from each other.

W represents an organic group including a cyclic structure.

o represents an integer of 1 to 3. p represents an integer of 0 to 10. q represents an integer of 0 to 10.

Xf represents a fluorine atom or an alkyl group substituted with at least one fluorine atom. The alkyl group preferably has 1 to 10 carbon atoms, and more preferably has 1 to 4 carbon atoms. In addition, the alkyl group substituted with at least one fluorine atom is preferably a perfluoroalkyl group.

Xf is preferably the fluorine atom or the perfluoroalkyl group having 1 to 4 carbon atoms. Xf is more preferably the fluorine atom or CF₃. It is particularly preferable that both Xfs are the fluorine atoms.

R₄ and R₅ each independently represent a hydrogen atom, a fluorine atom, an alkyl group, or an alkyl group substituted with at least one fluorine atom, and in a case where a plurality of R₄′s and R₅′s are present, they may be the same as or different from each other.

The alkyl group as each of R₄ and R₅ may have a substituent, and preferably has 1 to 4 carbon atoms. R₄ and R₅ are each preferably the hydrogen atom.

Specific examples and suitable aspects of the alkyl group substituted with at least one fluorine atom are the same as the specific examples and the suitable aspects, respectively, of Xf in General Formula (3).

L represents a divalent linking group, and in a case where L’s are present in plurality, they may be the same as or different from each other.

Examples of the divalent linking group include —COO—(—C(═O)—O—), —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), or a divalent linking group formed by combination of these plurality of groups. Among these, —COO—, —OCO—, —CONH—, —NHCO—, —CO—, —O—, —SO₂—, -COO-alkylene group-, -OCO-alkylene group-, -CONH-alkylene group-, or -NHCO-alkylene group- is preferable, and —COO—, —OCO—, —CONH—, —SO₂—, -COO-alkylene group -, or -OCO-alkylene group- is more preferable.

W represents an organic group including a cyclic structure. Above all, it is preferably a cyclic organic group.

Examples of the cyclic organic group include an alicyclic group, an aryl group, and a heterocyclic group.

The alicyclic group may be either monocyclic or polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Among those, an alicyclic group having a bulky structure having 7 or more carbon atoms, such as a norbornyl group, a tricyclodecanyl group, a tetracyclodecanyl group, a tetracyclododecanyl group, a diamantyl group, and an adamantyl group, can be used in the post-exposure baking (PEB) step is preferable from the viewpoint that it can suppress the in-plane diffusivity and improve a mask error enhancement factor (MEEF).

The aryl group may be monocyclic or polycyclic. Examples of the aryl group include a phenyl group, a naphthyl group, a phenanthryl group, and an anthryl group. Among those, a naphthyl group showing a relatively low light absorbance at 193 nm is preferable.

The heterocyclic group may be monocyclic or polycyclic, but a polycyclic heterocyclic group can further suppress diffusion of the acid. Further, the heterocyclic group may have aromaticity or may not have aromaticity. Examples of the heterocyclic ring having aromaticity include a furan ring, a thiophene ring, a benzofuran ring, a benzothiophene ring, a dibenzofuran ring, a dibenzothiophene ring, and a pyridine ring. Examples of the heterocyclic ring not having aromaticity include a tetrahydropyran ring, a lactone ring, a sultone ring, and a decahydroisoquinoline ring. As the heterocyclic ring in the heterocyclic group, the furan ring, the thiophene ring, the pyridine ring, or the decahydroisoquinoline ring is particularly preferable. Further, examples of the lactone ring and the sultone ring include the lactone structures and sultone structures exemplified in the above-mentioned resin.

The cyclic organic group may have a substituent. Examples of the substituent include an alkyl group (which may be either linear or branched, preferably having 1 to 12 carbon atoms), a cycloalkyl group (which may be any of a monocycle, a polycycle, and a spirocycle, and preferably has 3 to 20 carbon atoms), an aryl group (preferably having 6 to 14 carbon atoms), a hydroxyl group, an alkoxy group, an ester group, an amide group, a urethane group, a ureide group, a thioether group, a sulfonamide group, and a sulfonic acid ester group. Incidentally, the carbon constituting the cyclic organic group (carbon contributing to ring formation) may be carbonyl carbon.

o represents an integer of 1 to 3. p represents an integer of 0 to 10. q represents an integer of 0 to 10.

In one embodiment, it is preferable that in General Formula (3), o is an integer of 1 to 3, p is an integer of 1 to 10, and q is 0. Xf is preferably a fluorine atom, R₄ and R₅ are preferably both hydrogen atoms, and W is preferably a polycyclic hydrocarbon group. o is more preferably 1 or 2, and still more preferably 1. p is more preferably an integer of 1 to 3, still more preferably 1 or 2, and particularly preferably 1. W is more preferably a polycyclic cycloalkyl group, and still more preferably an adamantyl group or a diamantyl group.

### Cation

In General Formula (3), X⁺ represents a cation.

X⁺ is not particularly limited as long as it is a cation, but suitable embodiments thereof include cations (moieties other than Z⁻) in General Formula (ZI) which will be described later.

### Suitable Embodiments

Suitable embodiments of the specific acid generator include a compound represented by General Formula (ZI).

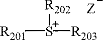

In General Formula (ZI),

R₂₀₁, R₂₀₂, and R₂₀₃ each independently represent an organic group.

The organic group as each of R₂₀₁, R₂₀₂, and R₂₀₃ generally has 1 to 30 carbon atoms, and preferably has 1 to 20 carbon atoms.

In addition, two of R₂₀₁ to R₂₀₃ may be bonded to each other to form a ring structure, and the ring may include an oxygen atom, a sulfur atom, an ester bond, an amide bond, or a carbonyl group. Examples of the group formed by the bonding of two of R₂₀₁ to R₂₀₃ include an alkylene group (for example, a butylene group and a pentylene group).

Z⁻ represents an anion in General Formula (3), and specifically represents the following anion.

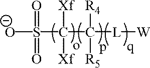

Incidentally, the specific acid generator may be a compound having a plurality of structures represented by General Formula (ZI). For example, it may be a compound having a structure in which at least one of R₂₀₁, ..., or R₂₀₃ in the compound represented by General Formula (ZI) is bonded to at least one of R₂₀₁, ..., or R₂₀₃ of another compound represented by General Formula (ZI) through a single bond or a linking group.

The compound (B) may be used alone or in combination of two or more kinds thereof.

The content of the compound (B) (a total sum of contents in a case where the compounds (B) are present in a plurality of kinds) in the photosensitive resist composition is preferably 0.1% to 30% by mass, more preferably 0.5% to 25% by mass, still more preferably 3% to 20% by mass, and particularly preferably 3% to 15% by mass, with respect to the total solid content of the photosensitive resist composition.

### Solvent (C)

The photosensitive resist-resist composition usually contains a solvent (C).

Examples of the solvent (C) include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

Specific examples of these solvents include those described in [0441] to [0455] of US2008/0187860A.

As the organic solvent, a mixed solvent obtained by mixing a solvent containing a hydroxyl group in the structure and a solvent containing no hydroxyl group may be used.

As the solvent containing a hydroxyl group and the solvent containing no hydroxyl group, the above-exemplified compounds can be appropriately selected, but as the solvent containing a hydroxyl group, alkylene glycol monoalkyl ether or alkyl lactate is preferable, and propylene glycol monomethyl ether (PGME, also known as 1-methoxy-2-propanol), methyl 2-hydroxyisobutyrate, or ethyl lactate is more preferable. Further, as the solvent containing no hydroxyl group, alkylene glycol monoalkyl ether acetate, alkyl alkoxypropionate, a monoketone compound which may contain a ring, a cyclic lactone, alkyl acetate, or the like is preferable, and among these, propylene glycol monomethyl ether acetate (PGMEA, also known as 1-methoxy-2-acetoxypropane), ethyl ethoxypropionate, 2-heptanone, γ-butyrolactone, cyclohexanone, or butyl acetate is more preferable, and propylene glycol monomethyl ether acetate, γ-butyrolactone, ethyl ethoxypropionate, or 2-heptanone is still more preferable.

The mixing ratio (mass ratio) of the solvent containing a hydroxyl group to the solvent not containing a hydroxyl group is 1/99 to 99/1, preferably 10/90 to 90/10, and more preferably 20/80 to 60/40. A mixed solvent including the solvent not containing a hydroxyl group in the amount of 50% by mass or more is particularly preferable from the viewpoint of coating evenness.

The solvent preferably includes propylene glycol monomethyl ether acetate, and is preferably a single solvent of propylene glycol monomethyl ether acetate or a mixed solvent of two or more kinds containing propylene glycol monomethyl ether acetate.

### Hydrophobic Resin (D)

The photosensitive resist composition may contain a hydrophobic resin (D). As the hydrophobic resin (D), the resin X described in the composition X_{A} for forming a non-photosensitive upper layer film can be suitably used. The hydrophobic resin is preferably solid at normal temperature (25° C.). Further, the glass transition temperature (Tg) is preferably 50° C. to 250° C., more preferably 70° C. to 250° C., still more preferably 80° C. to 250° C., particularly preferably 90° C. to 250° C., and most preferably 100° C. to 250° C. The hydrophobic resin preferably has a repeating unit having a monocyclic or polycyclic cycloalkyl group. The monocyclic or polycyclic cycloalkyl group may be included in either the main chain or a side chain of the repeating unit.

The weight-average molecular weight of the hydrophobic resin (D) in terms of standard polystyrene is preferably 1,000 to 100,000, more preferably 1,000 to 50,000, and still more preferably 2,000 to 15,000.

The hydrophobic resin (D) may be used alone or in combination of a plurality of kinds thereof.

The photosensitive resist composition may or may not contain the hydrophobic resin (D), but in a case where the hydrophobic resin (D) is contained, the content of the hydrophobic resin (D) in the photosensitive resist composition is generally 0.01% to 30% by mass, preferably 0.01% to 10% by mass, more preferably 0.05% to 8% by mass, and still preferably 0.1% to 7% by mass with respect to the total solid content in the photosensitive resist composition.

### Acid Diffusion Control Agent

The photosensitive resist composition preferably contains an acid diffusion control agent in order to reduce a change in performance over time from exposure to heating.

Preferred examples of the acid diffusion control agent include compounds having structures represented by Formulae (A) to (E).

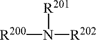

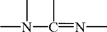

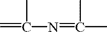

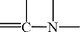

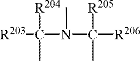

In General Formulae (A) to (E),

R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms), in which R²⁰¹ and R²⁰² may be bonded to each other to form a ring.

With respect to the alkyl group, as the alkyl group having a substituent, an aminoalkyl group having 1 to 20 carbon atoms, a hydroxyalkyl group having 1 to 20 carbon atoms, or a cyanoalkyl group having 1 to 20 carbon atoms is preferable.

R²⁰³, R²⁰⁴, R²⁰⁵, and R²⁰⁶ may be the same as or different from each other, and each represent an alkyl group having 1 to 20 carbon atoms.

The alkyl group in General Formulae (A) to (E) is more preferably unsubstituted.

Preferred examples of the compound include guanidine, aminopyrrolidine, pyrazole, pyrazoline, piperazine, aminomorpholine, aminoalkylmorpholine and piperidine. More preferred examples of the compound include a compound having an imidazole structure, a diazabicyclo structure, an onium hydroxide structure, an onium carboxylate structure, a trialkylamine structure, an aniline structure or a pyridine structure, an alkylamine derivative having a hydroxyl group and/or an ether bond, and an aniline derivative having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]non-5-ene, and 1,8-diazabicyclo[5,4,0]undec-7-ene. Examples of the compound having an onium hydroxide structure include triarylsulfonium hydroxide, phenacylsulfonium hydroxide, and sulfonium hydroxide having a 2-oxoalkyl group, specifically triphenylsulfonium hydroxide, tris(t-butylphenyl)sulfonium hydroxide, bis(t-butylphenyl)iodonium hydroxide, phenacylthiophenium hydroxide and 2-oxopropylthiophenium hydroxide. The compound having an onium carboxylate structure is formed by carboxylation of an anionic moiety of a compound having an onium hydroxide structure, and examples thereof include acetate, adamantane-1-carboxylate, and perfluoroalkyl carboxylate. Examples of the compound having a trialkylamine structure include tri(n-butyl)amine and tri(n-octyl)amine. Examples of the compound having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

In addition, as the acid diffusion control agent, those described as the basic compound which may be contained in the above-mentioned composition X_{A} for forming a non-photosensitive upper layer film can also be suitably used.

The acid diffusion control agents may be used alone or in combination of two or more kinds thereof.

The content of the acid diffusion control agent is generally 0.001% to 10% by mass, and preferably 0.01% to 5% by mass with respect to the total solid content of the photosensitive resist composition.

The photosensitive resist composition may include other components in addition to those described above.

Examples of such other components include a surfactant, an onium carboxylate salt, a dye, a plasticizer, a light sensitizer, a light absorbent, an alkali-soluble resin, a dissolution inhibitor, and a compound that promotes solubility in a developer (for example, a phenol compound with a molecular weight of 1,000 or less, an alicyclic or aliphatic compound having a carboxyl group).

The photosensitive resist composition can be prepared by dissolving the components in an organic solvent and performing filter filtration. The photosensitive resist composition can be applied onto a workpiece to form a photosensitive resist film. The filter used for the filter filtration is preferably a polytetrafluoroethylene-, polyethylene-, or nylon-made filter having a pore size of 0.1 µm or less, more preferably 0.05 µm or less, and still more preferably 0.03 µm or less. In the filter filtration, circulating filtration may be performed or the filtration may be performed by connecting plural kinds of filters in series or in parallel, as disclosed in JP2002-62667A, for example. In addition, the composition may be filtered in plural times. Further, the composition may be subjected to a deaeration treatment or the like before or after filtration through a filter.

### Workpiece

The workpiece is not particularly limited, and it is possible to use a substrate generally used in a process for manufacturing a semiconductor such as an IC, a process for manufacturing a circuit board for a liquid crystal, a thermal head, or the like, and other lithographic processes of photofabrication, and examples thereof include inorganic substrates such as silicon, SiN, SiO₂, and SiN, and coating type inorganic substrates such as SOG.

Before forming the photosensitive resist film, an antireflection film may be previously coated on the substrate.

As the antireflection film, any type of an inorganic film type such as titanium, titanium dioxide, titanium nitride, chromium oxide, carbon, and amorphous silicon, and an organic film type formed of a light absorber and a polymer material can be used. In addition, as the organic antireflection film, a commercially available organic antireflection film such as DUV-30 series or DUV-40 series manufactured by Brewer Science, Inc., AR-2, AR-3, or AR-5 manufactured by Shipley Company, L.L.C., or ARC series such as ARC29A manufactured by Nissan Chemical Industries, Ltd. can also be used.

### Pattern Forming Method

The pattern forming method of an embodiment of the present invention is a pattern forming method including disposing a photosensitive resist film on a workpiece, forming a non-photosensitive upper layer film using a composition for forming a non-photosensitive upper layer film produced by the above-mentioned method for producing a composition for forming a non-photosensitive upper layer film, on the photosensitive resist film, and exposing and developing the photosensitive resist film to form a pattern.

As a method of disposing the photosensitive resist film on the workpiece, the above-mentioned method of applying the photosensitive resist composition on the workpiece is used. The application method is not particularly limited, and a spin coating method, a spray method, a roll coating method, a dip method, or the like, which is known in the related art, can be used, with the spin coating method being preferable.

After applying the photosensitive resist composition, the workpiece may be heated (prebaked) as necessary. As a result of this, a film from which insoluble residual solvents have been removed can be uniformly formed. The temperature for the prebake is not particularly limited, but is preferably 50° C. to 160° C., and more preferably 60° C. to 140° C.

The film thickness of the photosensitive resist film is preferably 20 to 200 nm, and more preferably 30 to 100 nm.

In a case where a non-photosensitive upper layer film is formed on a photosensitive resist film using the composition X_{A} for forming a non-photosensitive upper layer film produced by the above-mentioned method for producing a composition for forming a non-photosensitive upper layer film, it is preferable to use the above-mentioned applying method.

The non-photosensitive upper layer film can also be formed by applying the composition X_{A} for forming a non-photosensitive upper layer film onto a photosensitive resist film and then performing prebaking (PB) as necessary. The prebaking temperature (hereinafter also referred to as a “PB temperature”) is preferably 100° C. or higher, more preferably 105° C. or higher, still more preferably 110° C. or higher, particularly preferably 120° C. or higher, and most preferably higher than 120° C.

The upper limit value of the PB temperature is not particularly limited, but may be, for example, 200° C. or lower, and is preferably 170° C. or lower, more preferably 160° C. or lower, and still more preferably 150° C. or lower.

The film thickness of the non-photosensitive upper layer film is not particularly limited, but from the viewpoint of transparency to an exposure light source, the topcoat with a thickness of usually 5 nm to 300 nm, preferably 10 nm to 300 nm, more preferably 20 nm to 200 nm, and still more preferably 30 nm to 100 nm is formed.

After forming the non-photosensitive upper layer film, the substrate is heated, as necessary.

From the viewpoint of a resolution, it is preferable that the refractive index of the non-photosensitive upper layer film is close to that of the photosensitive resist film.

The non-photosensitive upper layer film is preferably insoluble in an immersion liquid, and more preferably insoluble in water.

With regard to the receding contact angle of the non-photosensitive upper layer film, the receding contact angle (23° C.) of the immersion liquid with respect to the non-photosensitive upper layer film is preferably 50° to 100°, and more preferably 80° to 100°, from the viewpoint of immersion liquid followability.

The exposure can be performed by a generally known method, and for example, the photosensitive resist film having the non-photosensitive upper layer film formed thereon is irradiated with actinic rays or radiation through a predetermined mask. Here, the actinic ray-sensitive or radiation-sensitive film is preferably irradiated with actinic rays or radiation through an immersion liquid, but is not limited thereto. The exposure amount can be appropriately set, but is usually 1 to 100 mJ/cm².

The wavelength of the light source used in the exposure device is not particularly limited, but light at a wavelength of 250 nm or less is preferably used, and examples thereof include KrF excimer laser light (248 nm), ArF excimer laser light (193 nm), F₂ excimer laser light (157 nm), EUVlight (13.5 nm), and electron beams. Among these, ArF excimer laser light (193 nm) is preferably used.

In a case of carrying out liquid immersion exposure, before the exposure and/or after the exposure, the surface of the film may be cleaned with a water-based chemical before performing the heating which will be described later.

The immersion liquid is preferably a liquid which is transparent to exposure wavelength and has a minimum temperature coefficient of a refractive index so as to minimize the distortion of an optical image projected on the film.

In particular, in a case where the exposure light source is an ArF excimer laser light (wavelength: 193 nm), water is preferably used in terms of easy availability and easy handling, in addition to the above-mentioned viewpoints.

In a case of using water, an additive (liquid) that decreases the surface tension of water while increasing the interfacial activity may be added at a slight proportion. It is preferable that this additive does not dissolve the photosensitive resist film on a substrate, and has a negligible effect on the optical coat at the undersurface of a lens element. Water to be used is preferably distilled water. Further, pure water which has been subjected to filtration through an ion exchange filter or the like may also be used. As a result of this, it is possible to suppress the distortion of an optical image projected on the photosensitive resist film by the incorporation of impurities.

In addition, in a view of further improving the refractive index, a medium having a refractive index of 1.5 or more can also be used. This medium may be an aqueous solution or an organic solvent.

After the exposure, it is preferable to perform heating (bake, also referred to as PEB) and development (preferably further rinsing). As a result of this, a good pattern can be obtained. The temperature for PEB is not particularly limited as long as a good resist pattern is obtained, and is usually 40° C. to 160° C. PEB may be carried out once or plural times.

Development is performed using a developer. The developer may be an alkali developer or a developer including an organic solvent. A developing step using an alkali developer and a developing step using a developer including an organic solvent may be combined.

As the alkali developer, a quaternary ammonium salt typified by tetramethylammonium hydroxide is usually used, but in addition to this, an aqueous alkali solution such as an inorganic alkali, primary to tertiary amines, an alcoholamine, and a cyclic amine can also be used.

Specifically, as the alkali developer, for example, alkali aqueous solutions of inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcoholamines such as dimethyl ethanolamine and triethanolamine; quaternary ammonium salts such as tetramethylammonium hydroxide and tetraethylammonium hydroxide; cyclic amines such as pyrrole and piperidine; or the like can be used. Among these, an aqueous tetraethylammonium hydroxide solution is preferably used.

Further, an appropriate amount of alcohols and a surfactant may be added to the alkali developer. The alkali concentration of the alkali developer is usually 0.1% to 20% by mass. The pH of the alkali developer is usually 10.0 to 15.0.

A time period for performing development the using the alkali developer is usually 10 to 300 seconds.

The alkali concentration (and the pH) of the alkali developer and the developing time can be appropriately adjusted depending on the patterns formed.

cleaning may be carried out using a rinsing liquid after the development using an alkali developer, and as the rinsing liquid, pure water is used, or an appropriate amount of a surfactant may be added thereto before the use.

Furthermore, after the developing treatment or the rinsing treatment, a treatment for removing the developer or rinsing liquid adhering on the pattern by a supercritical fluid may be carried out.

In addition, a heating treatment can be carried out in order to remove moisture content remaining in the pattern after the rinsing treatment or the treatment using a supercritical fluid.

Examples of the developer (hereinafter also referred to as an organic developer) containing an organic solvent, include developers containing a polar solvent such as a ketone-based solvent, an ester-based solvent, an alcohol-based solvent, an amide-based solvent, and an ether-based solvent, and a hydrocarbon-based solvent.

Examples of the ketone-based solvent include those described in paragraph [0276] of WO2016/136596A.

Examples of the ester-based solvent include those described in paragraph [0276] of WO2016/136596A.

Examples of the alcohol-based solvent include those described in paragraph [0276] of WO2016/136596A.

Examples of the ether-based solvent include, for example, dioxane and tetrahydrofuran, in addition to the glycol ether-based solvent described in paragraph [0276] of WO2016/136596A.

As the amide-based solvent, for example, N-methyl-2-pyrrolidone, N,N-dimethylacetamide, N,N-dimethylformamide, hexamethylphosphoric triamide, 1,3-dimethyl-2-imidazolidinone, or the like can be used.

Examples of the hydrocarbon-based solvent include aromatic hydrocarbon-based solvents such as toluene and xylene; and aliphatic hydrocarbon-based solvents such as pentane, hexane, octane, and decane. In addition, the aliphatic hydrocarbon-based solvent which is a hydrocarbon-based solvent may be a mixture of compounds having the same number of carbon atoms but different structures. For example, in a case where decane is used as the aliphatic hydrocarbon-based solvent, 2-methylnonane, 2,2-dimethyloctane, 4-ethyloctane, isooctane, or the like which is a compound having the same number of carbon atoms and different structures, may be included in the aliphatic hydrocarbon-based solvent. In addition, only one kind or a plurality of kinds of the compounds as described above having the same number of carbon atoms and different structures may be included.

A plurality of these solvents may be mixed and used, or the solvent may be mixed with a solvent other than those described above or with water, and used. It should be noted that in order to sufficiently exhibit the effects of the present invention, the moisture content in the entire developer is preferably less than 10% by mass, and it is more preferable that the developer contains substantially no moisture.

That is, the amount of the organic solvent to be used with respect to the organic developer is preferably from 90% by mass to 100% by mass, and more preferably from 95% by mass to 100% by mass, with respect to the total amount of the developer.

Among these, as the organic developer, a developer containing at least one organic solvent selected from the group consisting of a ketone-based solvent, an ester-based solvent, an alcohol-based solvent, an amide-based solvent, and an ether-based solvent is preferable, a developer including a ketone-based solvent or an ester-based solvent is more preferable, and a developer including butyl acetate, butyl propionate, or 2-heptanone is still more preferable.

The vapor pressure of the organic developer is preferably 5 kPa or less, more preferably 3 kPa or less, and still more preferably 2 kPa or less, at 20° C. By setting the vapor pressure of the organic developer to 5 kPa or less, the evaporation on a substrate or in a development cup of the developer is suppressed, and the temperature evenness within a wafer plane is improved, whereby the dimensional evenness within a wafer plane is enhanced.

Specific examples of the solvent having a vapor pressure of 5 kPa or less (2 kPa or less) include the solvents described in paragraph [0165] of JP2014-71304A.

An appropriate amount of a surfactant may be added to the organic developer, as necessary.

The surfactant is not particularly limited, but for example, an ionic or nonionic, fluorine-based and/or silicon-based surfactant, or the like can be used. Examples of such a fluorine-based and/or silicon-based surfactant include surfactants described in JP1987-36663A (JP-S62-36663A), JP1986-226746A (JP-S61-226746A), JP1986-226745A (JP-S61-226745A), JP1987-170950A(JP-S62-170950A), JP1988-34540A(JP-S63-34540A), JP1995-230165A(JP-H07-230165A), JP1996-62834A (JP-H08-62834A), JP1997-54432A (JP-H09-54432A), JP1997-5988A (JP-H09-5988A), and US5405720A, US5360692A, US5529881A, US5296330A, US5436098A, US5576143A, US5294511A, and US5824451A, with the nonionic surfactant being preferable. The nonionic surfactant is not particularly limited, but the fluorine-based surfactant or the silicon-based surfactant is more preferably used.

The amount of the surfactant to be used is usually 0.001% to 5% by mass, preferably 0.005% to 2% by mass, and more preferably 0.01% to 0.5% by mass, with respect to the total amount of the developer.

The organic developer may also include a basic compound. Specific and preferred examples of the basic compound which can be included in the organic developer used in the present invention include those which will be described as the basic compounds which can be included in the resist composition.

Examples of the developing method include a method in which a substrate is immersed in a tank filled with a developer for a certain period of time (a dip method), a method in which a developer is heaped up to the surface of a substrate by surface tension and developed by standing for a certain period of time (a puddle method), a method in which a developer is sprayed on the surface of a substrate (a spray method), and a method in which a developer is continuously discharged on a substrate rotated at a constant rate while scanning a developer discharging nozzle at a constant rate (a dynamic dispense method).

In addition, after the step of performing development using a developer including an organic solvent, a step of stopping the development while replacing the solvent with another solvent may also be included.

A cleaning step using a rinsing liquid may be included after the step of performing the development using a developer including an organic solvent.

The rinsing liquid is not particularly limited as long as it does not dissolve the resist pattern, and a solution including a general organic solvent can be used. As the rinsing liquid, for example, a rinsing liquid containing at least one organic solvent selected from a hydrocarbon-based solvent, a ketone-based solvent, an ester-based solvent, an alcohol-based solvent, an amide-based solvent, and an ether-based solvent, described above as the organic solvent included in the organic developer is preferably used. More preferably, a step of performing the cleaning using a rinsing liquid containing at least one organic solvent selected from the hydrocarbon-based solvent, the ketone-based solvent, the ester-based solvent, the alcohol-based solvent, and the amide-based solvent is carried out. Still more preferably, a step of performing the cleaning using a rinsing liquid containing the hydrocarbon-based solvent, the alcohol-based solvent, or the ester-based solvent is carried out. Particularly preferably, a step of performing cleaning using a rinsing liquid containing a monohydric alcohol is carried out.

Here, examples of the monohydric alcohol used in the rinsing step include linear, branched, or cyclic monohydric alcohols, and specifically, 1-butanol, 2-butanol, 3-methyl-1-butanol, 3-methyl-2-butanol, tert-butyl alcohol, 1-pentanol, 2-pentanol, 3-methyl-2-pentanol, 4-methyl-2-pentanol, 1-hexanol, 2-hexanol, 3-hexanol, 4-methyl-2-hexanol, 5-methyl-2-hexanol, 1-heptanol, 2-heptanol, 3-heptanol, 4-methyl-2-heptanol, 5-methyl-2-heptanol, 1-octanol, 2-octanol, 3-octanol, 4-octanol, 4-methyl-2-octanol, 5-methyl-2-octanol, 6-methyl-2-octanol, 2-nonanol, 4-methyl-2-nonanol, 5-methyl-2-nonanol, 6-methyl-2-nonanol, 7-methyl-2-nonanol, 2-decanol, or the like can be used, with 1-hexanol, 2-hexanol, 1-pentanol, 3-methyl-1-butanol, or 4-methyl-2-heptanol being preferable.

Furthermore, examples of the hydrocarbon-based solvent used in the rinsing step include aromatic hydrocarbon-based solvents such as toluene and xylene; and aliphatic hydrocarbon-based solvents such as pentane, hexane, octane, decane (n-decane), and undecane.

In a case where the ester-based solvent is used as the rinsing liquid, a glycol ether-based solvent may be used, in addition to the ester-based solvent (one kind, or two or more kinds). As a specific example thereof in this case, an ester-based solvent (preferably butyl acetate) may be used as a main component, and a glycol ether-based solvent (preferably propylene glycol monomethyl ether (PGME)) may be used as a side component. As a result of this, residue defects are suppressed.

The respective components in plurality may be mixed and used, or the components may be mixed with an organic solvent other than the solvents, and used.

The moisture content of the rinsing liquid is preferably 10% by mass or less, more preferably 5% by mass or less, and particularly preferably 3% by mass or less. By setting the moisture content to 10% by mass or less, good development characteristics can be obtained.

The vapor pressure of the rinsing liquid is preferably 0.05 to 5 kPa, more preferably 0.1 to 5 kPa, and still more preferably 0.12 to 3 kPa, at 20° C. By setting the vapor pressure of the rinsing liquid to 0.05 to 5 kPa, the temperature evenness within a wafer plane is improved, and further, the dimensional evenness within a wafer plane is enhanced by inhibition of swelling due to the permeation of the rinsing liquid.

The rinsing liquid can also be used after adding an appropriate amount of a surfactant thereto.

In the rinsing step, the wafer which has been subjected to development using a developer including an organic solvent is subjected to a cleaning treatment using the rinsing liquid including the organic solvent. A method for the washing treatment is not particularly limited, and for example, a method in which a rinsing liquid is continuously discharged on a substrate rotated at a constant rate (a spin coating method), a method in which a substrate is immersed in a tank filled with a rinsing liquid for a certain period of time (a dip method), a method in which a rinsing liquid is sprayed onto a substrate surface (a spray method), or the like, can be applied. Among these, a method in which a washing treatment is carried out using the spin coating method, and a substrate is rotated at a rotation speed of 2,000 rpm to 4,000 rpm after washing, and then the rinsing liquid is removed from the substrate, is preferable. Further, it is preferable that a heating step (post bake) is included after the rinsing step. The residual developer and the rinsing liquid between and inside the patterns are removed by performing the bake. The heating step after the rinsing step is carried out at typically 40° C. to 160° C., and preferably at 70° C. to 95° C., and typically for 10 seconds to 3 minutes, and preferably for 30 seconds to 90 seconds.

Moreover, the pattern forming method of the embodiment of the present invention may include a developing step using an organic developer and a developing step using an alkali developer. A portion having a low exposure intensity is removed by development using an organic developer, and a portion having a high exposure intensity is removed by performing development using an alkali developer. By virtue of multiple development processes in which development is carried out in plural times in this manner, a pattern can be formed by keeping only a region with an intermediate exposure intensity from not being dissolved, so that a finer pattern than usual can be formed (the same mechanism as in paragraph [0077] of JP2008-292975A).

The present invention further relates to a method for manufacturing an electronic device, including the above-mentioned pattern forming method of the embodiment of the present invention, and an electronic device manufactured by the manufacturing method.

The electronic device of an embodiment of the present invention is suitably mounted on electric and electronic equipment (for example, home appliances, office automation (OA)-related equipment, media-related equipment, optical equipment, telecommunication equipment, and the like).

### EXAMPLES

Hereinbelow, the present invention will be described in more detail with reference to Examples. The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

### Synthesis of Resin X

As the resin X, resins X-1 to X-10 described below were used. All of the resins X-1 to X-10 were synthesized based on a known technique.

The types of the repeating units (corresponding monomers) contained in the resins X-1 to X-10, and the contents thereof (the content molar ratio of each repeating unit with respect to all the repeating units. unit: % by mole) are shown in Table 2. In addition, the weight-average molecular weights (Mw) and the dispersities (Mw/Mn) of the resins X-1 to X-10 are shown in Table 2.

The weight-average molecular weights (Mw) and the dispersities (Mw/Mn) of the resins X-1 to X-10 are values expressed in terms of polystyrene, measured by the above-mentioned GPC method (carrier: tetrahydrofuran (THF)). In addition, the content of the repeating unit in the resin was measured by means of ¹³C-nuclear magnetic resonance (NMR).

TABLE 2

| Resin X | Repeating unit 1 | | Repeating unit 2 | | Repeating unit 3 | | Repeating unit 4 | | Mw | Mw/Mn |
|---|---|---|---|---|---|---|---|---|---|---|
| | Type of monomer | Content (% by mole) | Type of monomer | Content (% by mole) | Type of monomer | Content (% by mole) | Type of monomer | Content (% by mole) | | |
| X-1 | M-1 | 60 | M-8 | 30 | M-14 | 10 | | | 6,800 | 1.9 |
| X-2 | M-7 | 20 | M-13 | 40 | M-14 | 40 | | | 6,900 | 1.8 |
| X-3 | M-2 | 55 | M-7 | 15 | M-9 | 15 | M-10 | 15 | 7,100 | 1.8 |
| X-4 | M-3 | 80 | M-7 | 20 | | | | | 6,900 | 1.9 |
| X-5 | M-5 | 65 | M-13 | 25 | M-14 | 10 | | | 6,800 | 1.8 |
| X-6 | M-6 | 55 | M-13 | 25 | M-14 | 20 | | | 7,000 | 1.8 |
| X-7 | M-4 | 65 | M-7 | 15 | M-12 | 15 | M-11 | 5 | 6,900 | 1.7 |
| X-8 | M-4 | 65 | M-12 | 35 | | | | | 7,000 | 1.9 |
| X-9 | M-3 | 10 | M-4 | 60 | M-7 | 15 | M-12 | 15 | 6,800 | 1.8 |
| X-10 | M-10 | 30 | M-12 | 70 | | | | | 6,800 | 1.8 |

The structures of the monomers M-1 to M-14 corresponding to the respective repeating units described in Table 2 are shown below.

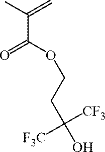

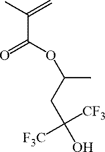

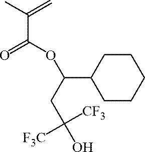

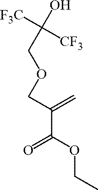

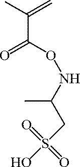

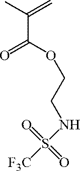

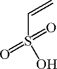

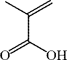

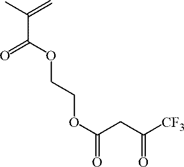

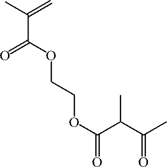

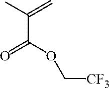

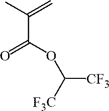

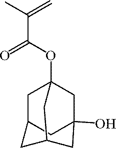

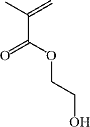

### Solvent

The names and the SP values of the solvents S-1 to S-8 used in Examples and Comparative Examples are shown in Table 3 below. PGMEA is propylene glycol monomethyl ether acetate and PGME is propylene glycol monomethyl ether.

TABLE 3

| Solvent | Name | SP Value (MPa^{½}) |
|---|---|---|
| S-1 | 4-Methyl-2-pentanol (MIBC) | 21.2 |
| S-2 | 2-Pentanol | 22.0 |
| S-3 | Diisoamyl ether | 15.6 |
| S-4 | Decane | 15.8 |
| S-5 | 1-Butanol | 23.2 |
| S-6 | PGMEA | 17.9 |
| S-7 | PGME | 23.0 |
| S-8 | Cyclohexane | 20.0 |

### Cleaning of Production Device for Composition X_{A} for Forming Non-Photosensitive Upper Layer Film

In each of Examples and Comparative Examples, the production device 10 for the composition X_{A} for forming a non-photosensitive upper layer film shown in FIG. 2 was cleaned by the following procedure. A polyethylene filter cartridge having a pore diameter of 20 nm was set in the filtration machine 4, and then 20 L of a cleaning liquid shown in Table 4 was supplied from a supply port (not shown) of the 100 L preparation tank 1. The inside of each of the preparation tank, the pipe, the pump, the filtration machine, and the valve of the production device was cleaned by the methods shown below, depending on whether or not the cleaning liquid was circulated. The number of times (number of times of cleaning) of cleaning performed by the method shown below in each of Examples and Comparative Examples is shown in Table 4.

In Table 4, in Examples and Comparative Examples in which the second cleaning liquid is described in addition to the first cleaning liquid, the first cleaning liquid is first used for cleaning, and the second cleaning liquid is then used for cleaning.

In addition, the production device was the one used for producing the composition X_{B} for forming a non-photosensitive upper layer film shown in Table 4 before performing the cleaning. More specifically, the production device used in each of Examples and Comparative Examples was the one used for producing a composition X_{B} for forming a non-photosensitive upper layer film described in the column of “Composition X_{B} for forming a non-photosensitive upper layer film produced at a previous time” in Table 4 before performing the cleaning.

### Case Without Circulation

After stirring the cleaning liquid present inside the preparation tank 1 with the stirrer 8 for 1 hour, the stirrer 8 was stopped and the valve 7 (extraction valve) was opened to discharge the cleaning liquid to the outside of the device.

### Case With Circulation

After stirring the cleaning liquid present inside the preparation tank 1 with the stirrer 8 for 1 hour, the stirrer 8 was stopped, the valve 5 (preparation tank valve) and the valve 6 (circulation valve) were opened, the valve 7 (extraction valve) was closed, the pump 3 was then started, and the cleaning liquid was circulated for 24 hours. The cleaning liquid was discharged to the outside of the device by opening the valve 7 (extraction valve).

TABLE 4

| | Composition Xₙ for forming non-photosensitive upper layer film produced at previous time | | First cleaning liquid | | SP_{W1} - SP_{B} (MPa^{½}) | Second cleaning liquid | | SP_{W2} - SP_{A} (MPa^{½}) | Composition X_{A} for forming non-photosensitive upper layer film produced this time | | Presence of absence of substitution | Number of times of cleaning | |
|---|---|---|---|---|---|---|---|---|---|---|---|---|---|
| | Type | S.P Value of solvent S_{B} SP_{B} (MPa^{½}) | Type and mass ratio | SP_{W5} (MPa^{½}) | | Type and mass ratio | SP_{W2} (MPa^{½}) | | Type | SP Value of solvent S_{A} SP_{A} (MPa^{½}) | | First cleaning liquid (times) | Second cleaning liquid (times) |
| Example 1 | TC-1 | 20.6 | S-1 = 100 | 21.2. | 0.6 | - | - | - | TC-1 | 20.6 | Absent | 1 | - |
| Example 2 | TC-1 | 20.6 | S-1 = 100 | 21.2. | 0.6 | S-2 = 100 | 22.0 | 0.8 | TC-2 | 21.2 | Present | 1 | 3 |
| Example 3 | TC-2 | 21.2 | S-2 = 100 | 22.0 | 0.8 | - | - | - | TC-3 | 22.2 | Absent | 1 | - |
| Example 4 | TC-2 | 21.2 | S1/S-4 = 90/10 | 20.7 | -0.5 | - | - | - | TC-4 | 20.7 | Present | 5 | - |
| Example 5 | TC-9 | 15.3 | S-4 = 100 | 15.8. | 0.5 | S-1 = 100 | 21.2 | 0.3 | TC-5 | 20.9 | Present | 5 | 5 |
| Example 6 | TC-6 | 21.9 | S-1 = 100 | 21.2 | -0.7 | - | - | | TC-6 | 21.9 | Absent | 1 | - |
| Example 7 | TC-8 | 23.2 | S-5 = 100 | 23.2 | 0.0 | S-1 = 100 | 21.2 | 0.3 | TC-7 | 20.9 | Absent | 1 | 1 |
| Example 8 | TC-1 | 20.6 | S-1 = 100 | 21.2 | 0.6 | S-5 = 100 | 23.2 | 0.0 | TC-8 | 23.2 | Present | 2 | 2 |
| Example 9 | TC-3 | 22.2 | S-2/S-5 = 80/20 | 22.2 | 0.0 | S-3 = 100 | 15.6 | 0.3 | TC-9 | 15.3 | Present | 5 | 5 |
| Example 10 | TC-4 | 20.7 | S-1/S-4 = 90/10 | 20.7 | 0.0 | S-1/S-3 = 40/60 | 17.8 | 0.0 | TC-10 | 17.8 | Present | 3 | 1 |
| Example 11 | TC-5 | 20.9 | S-1 = 100 | 21.2 | 0.3 | S-3 = 100 | 15.6 | -0.6 | TC-11 | 16.2 | Absent | 1 | 1 |
| Example 12 | TC-6 | 21.9 | S-2 = 100 | 22.0 | 0.1 | S-5 = 100 | 23.2 | 6.6 | TC-12 | 16.6 | Present | 1 | 3 |
| Comparative Example 1 | TC-1 | 20.6 | S-6 = 100 | 17.9 | -2.7 | - | - | - | TC-1 | 20.6 | Present | 5 | - |
| Comparative Example 2 | TC-1 | 20.6 | S-6 = 100 | 17.9 | -2.7 | S-7 = 100 | 23.0 | 1.8 | TC-2 | 21.2 | Absent | 1 | 1 |
| Comparative Example 3 | TC-1 | 20.6 | S-8 = 100 | 20.0 | -0.6 | S-1 = 100 | 21.2 | 0.3 | TC-7 | 20.9 | Absent | 1 | 1 |

### Measurement of Concentration of Resin in Cleaning Liquid

The concentration of the resin in the cleaning liquid was calculated using a gel permeation chromatography analysis method. Specifically, the concentration of a resin having an Mw of 3,000 or more was measured under the conditions of a solvent: tetrahydrofuran, a flow rate (sample injection amount): 10 µL, columns: TSK gel Multipore HXL-M manufactured by Tosoh Corporation, a column temperature: 40° C., a flow rate: 1.0 mL/min, and a detector: differential refractive index detector, using HLC-8120GPC manufactured by Tosoh Corporation as a GPC device. A calibration line was prepared by examining a relationship between the peak area and the concentration of the resin in advance in a chromatogram obtained by using the GPC device, and the concentration of the resin was calculated from the obtained peak area.

In Examples and Comparative Examples in which two kinds of cleaning liquids were used, the concentration of the resin in the second cleaning liquid, which was the cleaning liquid used later, was measured.

The concentration of the resin in the cleaning liquid in a case where the cleaning of the production device for the composition X_{A} for forming a non-photosensitive upper layer film was completed is shown in Table 8.

### Measurement of Particles in Liquid

The number of particles in a liquid having a particle diameter of 0.15 µm or more in the cleaning liquid was measured using a particle counter KS-41A (manufactured by Rion Co., Ltd.) in the liquid. The measurement was performed at room temperature (23° C.).

In Examples and Comparative Examples in which two kinds of cleaning liquids were used, the number of particles in the second cleaning liquid, which was the cleaning liquid used later, was measured.

The number of particles (number per 1 mL) in the cleaning liquid in a case where the cleaning of the production device for the composition X_{A} for forming a non-photosensitive upper layer film was completed is shown in Table 8.

### Production of Composition X_{A} for Forming Non-Photosensitive Upper Layer Film

The composition X_{A} for forming a non-photosensitive upper layer film was produced using the production device 10 for the composition X_{A} for forming a non-photosensitive upper layer film shown in FIG. 2, which had been cleaned. The type of the composition X_{A} for forming a non-photosensitive upper layer film produced in each of Examples and Comparative Examples is described in the column of “Composition X_{A} for forming non-photosensitive upper layer film produced this time” in Table 4.

The compositions TC-1 to TC-12 for forming a non-photosensitive upper layer film each contain the resin X and the solvent shown in Table 5 below in the blending amounts (parts by mass) shown in Table 5. Specifically, the resin X and the solvent shown in Table 5 were blended in the blending amounts (parts by mass) shown in Table 5 in the preparation tank after cleaning, and filtered through a filter having a pore diameter of 30 nm to produce compositions TC-1 to TC-12 for forming a non-photosensitive upper layer film.

The SP values of the solvents (in the case of a mixed solvent, the SP values of the mixed solvents) are also shown in Table 5. In a case where n kinds of solvents are present in the mixed solvent, the SP value (SPₘᵢₓ) of the mixed solvent can be determined by Expression (1). It should be noted that n represents an integer of 2 or more, i represents an integer of 1 to n, SPᵢ represents an SP value of each solvent, and Xi represents a content (% by mass) of each solvent with respect to the total solvent.

### Expression 2

$${\text{SP}}_{\text{mix}} = {\sum }_{\text{i=1}}^{\text{n}} \left({\text{SP}}_{\text{i}} ⋅ \frac{{\text{X}}_{\text{i}}}{100}\right)$$

In addition, the transmittance of an ArF excimer laser light (a light having a wavelength of 193 nm) of a non-photosensitive upper layer film having a film thickness of 30 nm formed using each composition for forming a non-photosensitive upper layer film is shown in Table 6. The transmittance for a light having a wavelength of 193 nm was calculated from an absorbance of a non-photosensitive upper layer film having a film thickness of 30 nm at a wavelength of 193 nm, formed by applying a solution of a composition for forming a non-photosensitive upper layer film prepared by the above-mentioned method onto a quartz glass substrate by spin coating, and performing prebaking at 100° C. An ellipsometer EPM-222 (manufactured by J.A. Woollam Company) was used for measuring the absorbance.

TABLE 5

| Composition for forming non-photosensitive upper layer film | Resin X | | | | | | Solvent | | | | | | |
|---|---|---|---|---|---|---|---|---|---|---|---|---|---|
| | Resin 1 | | Resin 2 | | Resin 3 | | Solvent 1 | | Solvent 2 | | Solvent 3 | | SP Value (MPa^{½}) |
| | Type | Blending amount [parts by mass] | Type | Blending amount [parts by mass] | Type | Blending amount [parts by mass] | Type | Blending amount [parts by mass] | Type | Blending amount [parts by mass] | Type | Blending amount [parts by mass] | |
| TC-1 | X-1 | 100 | | | | | S-1 | 4196 | S-3 | 466 | | | 20.6 |
| TC-2 | X-2 | 100 | | | | | S-1 | 4662 | | | | | 21.2 |
| TC-3 | X-3 | 100 | | | | | S-2 | 3730 | S-5 | 932 | | | 22.2 |
| TC-4 | X-4 | 100 | | | | | S-1 | 4196 | S-4 | 466 | | | 20.7 |
| TC-5 | X-7 | 100 | | | | | S-1 | 2798 | S-2 | 1398 | S-3 | 466 | 20.9 |
| TC-6 | X-1 | 60 | X-8 | 40 | | | S-1 | 3130 | S-5 | 1532 | | | 21.9 |
| TC-7 | X-3 | 30 | X-4 | 30 | X-7 | 40 | S-1 | 2564 | S-2 | 1632 | S-4 | 466 | 20.9 |
| TC-8 | X-5 | 100 | | | | | S-5 | 4662 | | | | | 23.2 |
| TC-9 | X-6 | 100 | | | | | S-4 | 4662 | | | | | 15.3 |
| TC-10 | X4 | 100 | | | | | S-1 | 1865 | S-3 | 2797 | | | 17.8 |
| TC-11 | X-9 | 100 | | | | | S-1 | 466 | S-3 | 4196 | | | 16.2 |
| TC-12 | X-10 | 100 | | | | | S-1 | 699 | S-4 | 3963 | | | 16.6 |

TABLE 6

| Composition for forming non-photosensitive upper layer film | Transmittance of ArF excimer laser light of non-photosensitive upper layer film having film thickness of 30 nm [%] |
|---|---|
| TC-1 | 98.4 |
| TC-2 | 98.8 |
| TC-3 | 98.0 |
| TC-4 | 97.5 |
| TC-5 | 97.9 |
| TC-6 | 98.2 |
| TC-7 | 98.6 |
| TC-8 | 97.9 |
| TC-9 | 97.8 |
| TC-10 | 98.8 |
| TC-11 | 99.0 |
| TC-12 | 98.8 |

### Preparation of Photosensitive Resist Composition

Each component listed in Table 7 was blended in a blending amount (parts by mass) shown in Table 7 and filtered through a filter having a pore diameter of 30 nm to prepare a photosensitive resist composition PR-1.

TABLE 7

| Photosensitive resist composition | Acid-decomposable resin | | Photoacid generator | | Acid diffusion control agent | | Solvent | |
|---|---|---|---|---|---|---|---|---|
| | Type | Blending amount [parts by mass] | Type | Blending amount [parts by mass] | Type | Blending amount [parts by mass] | Type | Blending amount [parts by mass] |
| PR-1 | N-1 | 100 | P-1 | 8 | D-1 | 1 | F-1/F-2/F-3 | 2,900/1,250/100 |

### Acid-Decomposable Resin

The structural formula, the Mw, and the Mw/Mn of the acid-decomposable resin N-1 included in the photosensitive resist composition PR-1 are as follows. The unit of the content rate of the repeating unit is % by mole.

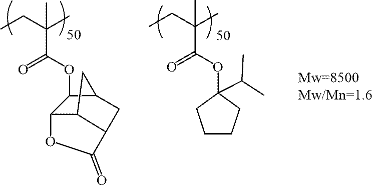

### Photoacid Generator

The photoacid generator P-1 included in the photosensitive resist composition PR-1 is triphenylsulfonium nonafluoro-n-butanesulfonate.

### Acid Diffusion Control Agent

The acid diffusion control agent D-1 included in the photosensitive resist composition PR-1 is a compound represented by the following structural formula.

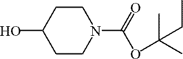

### Solvent

The solvents F-1 to F-3 included in the photosensitive resist composition PR-1 are the following compounds, respectively.
F-1: Propylene glycol monomethyl ether acetate (PGMEA)
F-2: Cyclohexanone
F-3: γ-Butyrolactone

### Pattern Formation and Defect Evaluation: ArF Liquid Immersion Exposure

A composition for forming an organic antireflection film, ARC29SR (manufactured by Brewer Science, Inc.), was applied onto a silicon wafer and baked at 205° C. for 60 seconds to form an antireflection film having a film thickness of 98 nm. The photosensitive resist composition PR-1 was applied onto the formed antireflection film and baked at 100° C. for 60 seconds to form a photosensitive resist film having a film thickness of 90 nm. Next, a non-photosensitive upper layer film was formed on the photosensitive resist film using the composition X_{A} for forming a non-photosensitive upper layer film shown in Table 4 above. The film thickness of the non-photosensitive upper layer film was 30 nm.

The photosensitive resist film was exposed upon irradiation with light from the non-photosensitive upper layer film side, using an ArF excimer laser immersion scanner (manufactured by ASML; XT1700i, NA1.20, Dipole, outer sigma: 0.950, inner sigma: 0.850, Y deflection). The exposure was performed through a 6% halftone mask of a 1:1 line-and-space pattern with a line width of 45 nm. Ultrapure water was used as the immersion liquid.

The resist film after the exposure was baked at 90° C. for 60 seconds, developed with an aqueous tetramethylammonium hydroxide solution (2.38% by mass) for 30 seconds, and then rinsed with pure water for 30 seconds. A wafer on which the resist pattern had been formed was obtained in this manner.

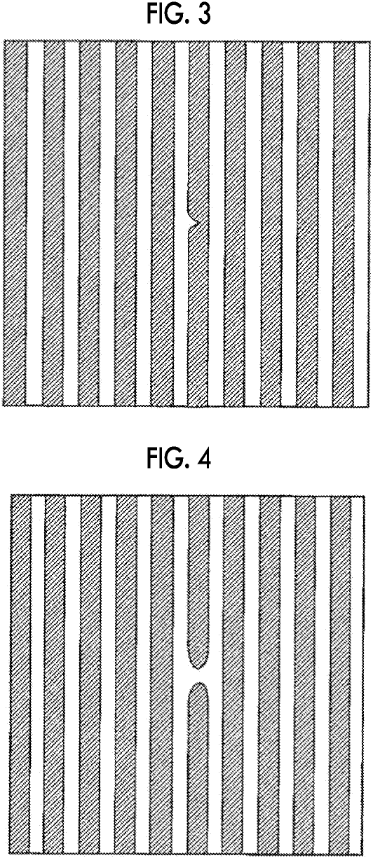

The wafer on which the resist pattern had been formed was inspected with a defect evaluation device UVision 5 manufactured by Applied Materials, Inc., and a defect map was created. Thereafter, an image of a defect was acquired using SEMVision G4 (manufactured by Applied Materials, Inc.), and the number of actual defects per sheet of the wafer was calculated. Furthermore, the actual defects generated in the wafer are observed as an image as shown in FIG. 3 and FIG. 4, for example. The results are shown in Table 8.

TABLE 8

| | Evaluation results of cleaning liquid | | Evaluation results of pattern |
|---|---|---|---|
| | Concentration of resin in cleaning liquid (ppm by mass) | Number of particles in liquid (particles/mL) | Number of pattern defects (pattern defects/wafer) |
| Example 1 | 6 | 2.0 | 145 |
| Example 2 | 5 | 2.5 | 140 |
| Example 3 | 8 | 3.0 | 170 |
| Example 4 | 4 | 2.0 | 135 |
| Example 5 | 2 | 1.0 | 82 |
| Example 6 | 3 | 1.0 | 104 |
| Example 7 | 1 | 0.5 | 56 |
| Example 8 | 2 | 1.0 | 90 |
| Example 9 | 5 | 3.5 | 140 |
| Example 10 | 3 | 1.0 | 86 |
| Example 11 | 2 | 1.0 | 96 |
| Example 12 | 10 | 5.0 | 192 |
| Comparative Example 1 | 15 | 8.0 | 320 |
| Comparative Example 2 | 25 | 10.0 | 400 |
| Comparative Example 3 | 12 | 4.0 | 300 |

As shown in Table 8, it was found that the generation of pattern defects can be suppressed by the method for producing a composition for forming a non-photosensitive upper layer film of the embodiment of the present invention.

According to the present invention, it is possible to provide a method for producing a composition for forming a non-photosensitive upper layer film, which is capable of forming a pattern having suppressed generation of defects, a pattern forming method, and a method for manufacturing an electronic device.

Although the present invention has been described in detail with reference to specific embodiments, it will be apparent to those skilled in the art that various changes and modifications can be made without departing from the spirit and the scope of the present invention.

### EXPLANATION OF REFERENCES

1: preparation tank
2: pipe
3: pump
4: filtration machine
5: valve
6: valve
7: valve
8: stirrer
9: container
10: production device

What is claimed is:

1. A method for producing a composition for forming a non-photosensitive upper layer film that is disposed on a workpiece and a photosensitive resist film, the production method comprising:
cleaning a production device for a composition X_{A} for forming a non-photosensitive upper layer film with a cleaning liquid to clean the production device until a concentration of a resin included in the cleaning liquid reaches 10 ppm by mass or less,
discharging the cleaning liquid from the production device, and producing the composition X_{A} for forming a non-photosensitive upper layer film using the production device,
wherein the cleaning, the discharging, and the producing are performed in this order.

2. The method for producing a composition for forming a non-photosensitive upper layer film according to claim 1,
wherein the concentration of the resin is calculated using a gel permeation chromatography analysis method.

3. The method for producing a composition for forming a non-photosensitive upper layer film according to claim 1,
wherein the production device includes a preparation tank, a pipe, a pump, a filtration machine, and a valve, and
wherein the inside of each of the preparation tank, the pipe, the pump, the filtration machine, and the valve is cleaned by circulating the cleaning liquid.

4. The method for producing a composition for forming a non-photosensitive upper layer film according to claim 1,
wherein the production device is a production device that is used for producing a composition X_{B} for forming a non-photosensitive upper layer film containing a solvent S_{B} before producing the composition X_{A} for forming a non-photosensitive upper layer film, and

|SP_{W} - SP_{B}|, which is an absolute value of a difference between a solubility parameter SP_{W} of the cleaning liquid and a solubility parameter SP_{B} of the solvent S_{B}, is less than 1.0 MPa^{½}.

5. The method for producing a composition for forming a non-photosensitive upper layer film according to claim 4,
wherein the cleaning of the production device is performed using at least two kinds of cleaning liquids including a first cleaning liquid and a second cleaning liquid,
the composition X_{A} for forming a non-photosensitive upper layer film contains a solvent Sa,

|SP_{W1} - SP_{B}|, which is an absolute value of a difference between a solubility parameter SP_{W1} of the first cleaning liquid and the solubility parameter SP_{B} of the solvent S_{B}, is less than 1.0 MPa^{½}, and

|SP_{W2} - SP_{A}|, which is an absolute value of a difference between a solubility parameter SP_{W2} of the second cleaning liquid and the solubility parameter SP_{A} of the solvent S_{A}, is less than 1.0 MPa^{½}.

6. The method for producing a composition for forming a non-photosensitive upper layer film according to claim 1,
wherein the cleaning liquid includes at least 4-methyl-2-pentanol.

7. The method for producing a composition for forming a non-photosensitive upper layer film as according to claim 1,
wherein a transmittance of an ArF excimer laser light of a non-photosensitive upper layer film, which has a film thickness of 30 nm and is formed using the composition X_{A} for forming a non-photosensitive upper layer film, is 80% or more.

8. The method for producing a composition for forming a non-photosensitive upper layer film according to claim 1,
wherein the composition X_{A} for forming a non-photosensitive upper layer film contains at least one of an alcohol-based solvent or an ether-based solvent.

9. The method for producing a composition for forming a non-photosensitive upper layer film according to claim 1,
wherein the composition X_{A} for forming a non-photosensitive upper layer film contains a resin having a repeating unit represented by General Formula (I), 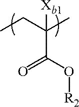
in the General Formula (I), X_{b1} represents a hydrogen atom, an alkyl group, a cyano group, or a halogen atom, and R₂ represents an organic group.

10. The method for producing a composition for forming a non-photosensitive upper layer film according to claim 9,
wherein the resin has an acid group.

11. The method for producing a composition for forming a non-photosensitive upper layer film according to claim 9,
wherein the resin has a fluorine-containing group.

12. The method for producing a composition for forming a non-photosensitive upper layer film according to claim 9,
wherein the resin has no acid-decomposable group.

13. The method for producing a composition for forming a non-photosensitive upper layer film according to claim 1,
wherein the composition X_{A} for forming a non-photosensitive upper layer film contains two or more kinds of resins.

14. A pattern forming method comprising:
disposing a photosensitive resist film on a workpiece,
forming a non-photosensitive upper layer film using a composition for forming a non-photosensitive upper layer film produced by the method for producing a composition for forming a non-photosensitive upper layer film according to claim 1, on the photosensitive resist film, and
exposing and developing the photosensitive resist film to form a pattern.

15. A method for manufacturing an electronic device, comprising the pattern forming method according to claim 14.
